(19) United States
(12) Patent Application Publication
(10) Pub. No.: US 2005/0139249 A1
(43) Pub. Date: Jun. 30, 2005

(54) Thermoelectric module and a method of manufacturing the same

(76) Inventors: Tatsuhiko Ueki, Tokyo (JP); Yoshinori Nakamura, Tokyo (JP); Yuji Hiratani, Tokyo (JP)

Correspondence Address: CANTOR COLBURN, LLP, 55 GRIFFIN ROAD SOUTH, BLOOMFIELD, CT, 06002, US

(21) Appl. No.: 11/006,073

(22) Filed: Dec. 6, 2004

Related U.S. Application Data
(63) Continuation of application No. PCT/JP03/07194, filed on Jun. 6, 2003.

(30) Foreign Application Priority Data
Jun. 6, 2002 (JP) 2002-165094
Oct. 4, 2002 (JP) 2002-292570
Oct. 10, 2002 (JP) 2002-297465
Mar. 19, 2003 (JP) 2003-76217
Mar. 20, 2003 (JP) 2003-78117
May 30, 2003 (JP) 2003-153770

(51) Int. Cl. H01L 35/28

(52) U.S. Cl. 136/211; 136/212

(57) ABSTRACT

A thermoelectric module comprises an upper insulating substrate and a lower insulating substrate; an upper electric circuit metal layer and a lower electric circuit metal layer bonded respectively to the surfaces of said insulating substrates which are positioned face to face; an upper blast stopper layer and a lower blast stopper layer fabricated respectively on said electric circuit metal layers; an upper bonding layer and a lower bonding layer fabricated respectively on said blast stopper layers; and a plurality of [symbol] -shaped elements consisting of a pair of the P-type semiconductor element and N-type semiconductor element which are fabricated between said upper and lower bonding layers and are electrically connected in series through said upper and lower blast stopper layers.

### CROSS-REFERENCE TO RELATED APPLICATION

The present application is a continuation of PCT/JP03/07194, filed on Jun. 6, 2003, the entire contents of which are incorporated herein by reference, and which claims the benefit of the dates of the earlier filed Japanese Patent Applications, having JP 2002-165094 filed on Jun. 6, 2002, JP 2002-292570 filed on Oct. 4, 2002, JP 2002-297465 filed on Oct. 10, 2002, JP 2003-076217 filed on Mar. 19, 2003, JP 2003-078117 filed on Mar. 20, 2003 and JP 2003-153770 filed on May 30, 2003.

### TECHNICAL FIELD

This invention relates to a thermoelectric module which comprises a P-type and a N-type semiconductor, more particularly a thermoelectric module having a function of a power generator by temperature difference, namely Seebeck effect, or a function of an electric cooler and heater, namely Peltier effect, and a method for manufacturing. Furthermore, this invention relates to a module including a micro element such as a micro electronic element or a micro semiconductor element, and a method for making a connection at a narrow pitch for micro elements.

### BACKGORUND

In General, a thermoelectric element is made by fabricating a PN junction comprising a P-type semiconductor and a N-type semiconductor which is connected via an electrical circuitry metal layer in series between thereof.

The thermoelectric element has a Seebeck effect which function to generate an electric power when a temperature difference is made between the junction part, and a Peltier effect which function to cool down a one side of the junction part and heat up another side of the junction part when an electric current flows thereto. Because of this characteristics, this element can be used as a cooling unit or a power generator.

Also it can be used as a thermoelectric module by connecting some dozens or hundreds of the thermoelectric elements in series. The module is constructed in one body between substrates having an electrical circuitry metal layer thereon to form a PN junction pair.

Examples of a thermoelectric module and its process are disclosed in Provisional Publication No. 2001-332774. The disclosed structure of the thermoelectric module has following construction. This comprises a P-type thermoelectric element made of a P-type thermoelectric semiconductor, and a N-type thermoelectric element made of N-type thermoelectric semiconductor, then bonding a pair of P-type thermoelectric element and N-type thermoelectric element to form a P—N junction, and connecting via an electrode.

The construction of the thermoelectric element comprises, two substrates where aligned opposite like sandwich the P-type and the N-type thermoelectric element, and a bonding material to bond the P-type and the N-type thermoelectric element with the electrical circuitry metal layer which is facing to the thermoelectric element and has a larger area than the surface of the thermoelectric element.

The construction enables easy contact of the electrodes with the P-type and N-type thermoelectric elements even the position shifts during the bonding process between the thermoelectric elements. Also it enables to reduce a defect of poor contact caused by misalignment during the bonding process.

Although the shape of the thermoelectric element is not referred to, as described later, a dicing saw which is typically used for slicing a silicone substance is used in the manufacturing process. And hence, the P-type thermoelectric element and the N-type thermoelectric element disclosed in the conventional embodiment are made into the shape of square pillar's arrangement.

Furthermore, a method for manufacturing the thermoelectric element comprises the steps of:
bonding a P-type thermoelectric semiconductor material and a N-type thermoelectric semiconductor material on separate substrate;
slicing a P-type thermoelectric semiconductor material and a N-type thermoelectric semiconductor material by a dicing saw;
fabricating a plurality of P-type thermoelectric elements and N-type thermoelectric elements on the substrates;
fabricating an electric circuitry metal layer on the substrate which confronting to the top of the P-type thermoelectric element and N-type thermoelectric element so large;
placing two substrates facing to each other; and
bonding the top part of the P-type thermoelectric element and N-type thermoelectric element with the substrate where aligned corresponding thereto.

The problem with the conventional method is a method using a dicing saw when making a P-type thermoelectric element and a N-type thermoelectric element.

A dicing saw runs only in a direction of a straight line or the right-angled direction, therefore only square pillar of P-type or N-type thermoelectric element can be made.

This is a disadvantage as unable to reduce an arbitrary shape of a P-type and N-type thermoelectric element.

Furthermore, when mounting an electronic element or a semiconductor element on a substrate, the electrodes of the electronic element or the semiconductor element are bonded with the circuit metal layer. In this case, a flat shape electrodes of the element are bonded. As the size of the electronic element or the semiconductor element become further miniaturized and, in that a micro electric element and a micro semiconductor element, the bonding material inserted between the electric circuit metal layer on the substrate and the electrodes of a micro electronic element or a micro semiconductor product is likely to swell out around the circumference of the electrodes and that may cause a short circuit problem. Therefore, if miniaturization (i.e., downsizing) of an electronic element or a semiconductor element progresses further, it is likely to become a barrier for a narrow pitch and high density mounting and module miniaturization.

FIG. 4-4 is a drawing describing the conventional method of bonding the electric circuit metal layer on the substrate with the electrode of a micro electronic element or a semiconductor element. This describes about a mounting method in case of no gap made between the electric circuit metal layer and the electrodes of the micro electronic element.

As illustrated in FIG. 4-4, a bonding material is placed between the electrode 101 of the substrate 100 and the micro element 102 such as a micro electric element or a micro semiconductor element, and the electrode 103 of the micro element and the electrode 101 of the substrate is joined by pressing the micro element 102 towards the electrode 101 through the bonding material.

When giving a heat and a pressure to the electrode of the micro element and the electrode of the substrate, the contact is made by flat plate each other between the electrode 103 of the micro element and the electrode 101 of the substrate, the bonding material is forced and swell s out around the circumference of the micro element and the electrodes. Consequently, the micro element gets wet with the bonding material such as a soldering material and new chemical compound is made and that degrades its performance. Furthermore, as illustrated in FIG. 4-4, when taking into the consideration of swelling of the bonding material, the spacing between adjacent micro elements tends to be larger, the excess bonding material swelled restricts the narrower pitch of the high-density mounting.

FIG. 4-5 is explaining another conventional junction method to make a contact between the electric circuit metal layer of the substrate and the electrodes of the micro electronic element and a micro semiconductor element. In this case, it is mounted when the micro element is kept floating. As illustrated in FIG. 4-5, the bonding material is prepared on the upper surface of the electrode 101 of the substrate 100 which placed opposite to the micro element 102 such as a micro electronic element and a micro semiconductor element. The bonding material is prepared on the upper surface of the electrode 101 of the substrate 100. Consequently, it is likely not reaching the electrode 103 of the micro element 102 such as micro electronic element and a micro semiconductor element, if it is maintained at predetermined height as shown in FIG. 4-5 even keeping a pressure on the micro element 102 such as micro electronic element and a micro semiconductor element. In that, if the thickness of bonding material layer is thicker than the pre-designed value in order to fill a gap, it is likely to cause a short circuit. Therefore, a tight thickness control of bonding material is needed to keep it under the pre-designed thickness. As described above, a gap between the bonding material and the electrode may be made some cases, therefore the tight height control is needed for the mounting method of floating the micro element. An apparatus of soldering terminals of an electric element on the printed circuit board is disclosed in the Japanese Patent Provisional Publication No. Heisei 4-155946 as another example. Furthermore, as mentioned above, in the conventional junction method, the contact between the electrode of the micro element and the electrode of the substrate is carried out by a flat plate and the bonding material swells out around the circumference of the electrode. Consequently, there has been a problem that the micro element gets wet with the bonding material such as a soldering material and new chemical compound is made and hence that degrades its performance.

Also, there has been a problem with the bulging bonding material restricting a progress of narrow pitch and high density mounting and module miniaturization.

Furthermore, if the thickness of bonding material layer exceed the pre-designed value, it is likely to cause a short circuit. Therefore, a thickness of the bonding material is needed to control it under the pre-designed thickness. As described above, a gap between the bonding material and the electrode may be made some cases, therefore the tight height control is needed for the mounting method of floating the micro element and hence it cause an increasing of a manufacturing cost.

In addition, there has been a problem with a non-uniform shape of the junction and a protruding portion with an acute angle which is likely to cause a mechanical stress concentration and to affect the reliability performance even the tight height control is realized when the mounting. When adopting a method for mounting with that height control and the electrical resistance and the heat resistance is needed to keep at low value at, a much amount of the bonding material layer left between the electrode of the small element and the electrode of the substrate makes higher electrical resistance and heat resistance, hence it is likely to cause a problem of degrading the module performance.

FIG. 5-6 is showing a conventional process for the substrate by using a sand blasting. As illustrated in FIG. 5-6, a masking material 116 is fabricated on the surface of the substrate 111, and an abrasive material 70 is blasted over the masking. When perforating, cutting or the like are carried out by a sand blasting, the width tends to be made smaller as the depth of processing area goes deeper as illustrated in FIG. 5-6(b). When viewing the cross section, as designated by “130”, the portion left without cutting is made a skirt curving and side wall of it is made a non-perpendicular plate.

FIG. 5-7 is a schematic perspective view showing a thermoelectric module 111 which is made by the conventional process for the substrate as an example by using a sand blasting.

FIG. 5-8 is a sectional view of the line A-A in the FIG. 5-7.

As illustrated in FIG. 5-7 and 5-8, when a sand blasting is used to slice the thermoelectric element 111 and process it from the top side over the substrate, the upper part 112 is easily cut in larger but the bottom part 113 is hard for the processing, and hence the shape of the element is made with a wider width at the top than the bottom part, and the area of cross section which is parallel to the top surface and the bottom surface, is gradually increasing along from the top surface 112 to the bottom surface 113 and is made as tapered line designated by “115”.

Here the configuration of the apparatus is assumed that the processed wafer is placed approximately horizontal, the upper surface is covered by a mask and the sand blasting is applied from the top side.

The side processed by sand blasting first time or an upper side of the mask is named as top surface, and the opposite side is named as a bottom surface.

As long as the same relation of the relative position is maintained, same definition is applicable even when the apparatus stands inclined.

When a sand blasting is applied for a long time in order to form the wall further perpendicular plane, the mask may be worn out and become so smaller than an original shape. Like this, the area is made different between the top surface and the bottom surface of the thermoelectric semiconductor element in the thermoelectric module, hence it restricts to increase the density of an arrangement of the elements.

The original purpose of using a sand blasting is to get high density arrangement of the elements by utilizing its processing capability to make a fine shape, If it is not feasible, there is no advantage compared with other manufacturing methods. So, the capability of finishing the wall side in perpendicular plane is important, however it is difficult to form it incomplete perpendicular line by a sand blasting.

The one of purposes of the invention is to provide a method of producing an arbitrary shape, for example a hexagon shape P-type or N-type thermoelectric element, but not limited to those but also any free arbitrary shape of P-type or N-type thermoelectric element in very short process time.

Another purpose of the invention is to provide a method for processing the substrate of the thermoelectric semiconductor, and a method of manufacturing the thermoelectric module which is capable for high density arrangement by solving the problem in the conventional methods described above.

One more another purposes of the invention is to provide a method for processing a narrow pitch and a module comprising a micro element such as a micro electric element, micro semiconductor element with high reliability, high performance and low cost.

### SUMMARY OF THE INVENTION

The embodiment 1-1 according to the invention is a thermoelectric module comprises:
(a) an upper insulating substrate and a lower insulating substrate;
(b) an upper electric circuit metal layer and a lower electric circuit metal layer bonded respectively to the surfaces of said insulating substrates which are positioned face to face;
(c) an upper blast stopper layer and a lower blast stopper layer fabricated respectively on said electric circuit metal layers;
(d) an upper bonding layer and a lower bonding layer fabricated respectively on said blast stopper layers; and
(e) a plurality of [symbol] -shaped elements consisting of a pair of the P-type semiconductor element and N-type semiconductor element which are fabricated between said upper and lower bonding layers and are electrically connected in series through said upper and lower blast stopper layers.

The embodiment 1-1′ according to the invention is a thermoelectric module comprises:
(a) an upper insulating substrate and a lower insulating substrate;
(b) an upper electric circuit metal layer and a lower electric circuit metal layer bonded respectively to the surfaces of said insulating substrates which are positioned face to face;
(c) an upper bonding layer and a lower bonding layer fabricated respectively on said electric circuit metal layers;
(d) an upper blast stopper layer and a lower blast stopper layer fabricated respectively on said bonding layers; and
(e) a plurality of [symbol] -shaped elements consisting of a pair of the P-type semiconductor element and N-type semiconductor element which are fabricated between said upper and lower blast stopper layers and are electrically connected in series through said upper and lower blast stopper layers.

The embodiment 1-2 according to the invention is a thermoelectric module wherein a pair of P-type and N-type semiconductor are made of a P-type and N-type Bi—Te group semiconductor respectively.

The embodiment 1-3 according to the invention is a thermoelectric module wherein the electric circuit metal layer is made of a metal selected from a group consist of Cu, Cr, Ni, Ti, Al, Au and Si or an alloy thereof, or a laminated layer thereof.

The embodiment 1-4 according to the invention is a thermoelectric module wherein the blast stopper layer is made of a metal selected from a group consist of Cu, Ti, Cr, W, Mo, Pt, Zr, Si and C, or an alloy thereof.

The embodiment 1-5 according to the invention is a thermoelectric module wherein the blast stopper layer is made of a conductive material of a nitride, carbide, or oxide compound consisting of a chemical element selected from a group consisting of Al, Ti, Zr and C.

The embodiment 1-6 according to the invention is a thermoelectric module wherein the junction layer is made of a chemical element selected from a group consisting of Au, Ag, Ge, In, P, Si, Sn, Sb, Pb, Bi and Cu or an alloy thereof.

The embodiment 1-7 according to the invention is a thermoelectric module wherein a space formed by a plurality of [symbol] -shaped elements is filled with a insulating synthetic resin.

The embodiment 1-8 according to the invention is a method for manufacturing a thermoelectric module comprising an upper and a lower insulating substrates, electric circuit metal layers bonded respectively to the surfaces of said substrate which are positioned face to face, blast stopper layers fabricated respectively on said electric circuit metal layers, bonding layers fabricated on said blast stopper layers; and a plurality of [symbol] -shaped elements consisting of a pair of the P-type semiconductor element and N-type semiconductor element which are fabricated between said bonding layers and are electrically connected in series through said upper and lower blast stopper layers,

said method comprises the steps of:
preparing the substrate having the electric circuit metal layer and the blast stopper layer in a pre-designed pattern;
preparing a plate type P-type or N-type semiconductor having the bonding layer fabricated thereon;
bonding the surface of the bonding layer to the blast stopper layer fabricated on said substrate;
coating a photoresist;
forming a pre-designed pattern by an exposure;
further, by a micro blasting an abrasive, eliminating said bonding layer and said semiconductor layer of the area where the photoresist has been removed;
constructing a first part having said semiconductor layer protruded from one side of said substrate;
removing a residue of the photoresist;
and by repeating the same process as described above, constructing a second part using a different polarity semiconductor of a P-type or N-type from said first part which has a shape wherein the P-type and N-type are arranged alternatively when assembled facing to the first part;
then, reversing said second part by 180 degree, mating to the first part and bonding both parts together.

The embodiment 1-8′ according to the invention is a method for manufacturing a thermoelectric module comprising-an upper and a lower insulating substrates, electric circuit metal layers bonded respectively to the surfaces of said substrates which are positioned face to face, bonding layers fabricated respectively on said electric circuit metal layers, blast stopper layers fabricated respectively on said bonding layers; and a plurality of [symbol] -shaped elements consist of a pair of the P-type semiconductor element and N-type semiconductor element which are fabricated between said blast stopper layers and are electrically connected in series through said upper and lower blast stopper layers,

said method comprises the steps of:
preparing the insulating substrate having the electric circuit metal layer and the bonding layer in a pre-designed pattern;
preparing the plate of P-type or N-type semiconductor having the blast stopper layer fabricated thereon;
bonding the surface of said blast stopper layer to the bonding layer fabricated on said substrate;
coating a photoresist;
forming a pre-designed pattern by an exposure;
further, by a micro blasting, eliminating said semiconductor layer of the area where the photoresist has been removed;
constructing a first part having said semiconductor layer protruded from one side of said substrate;
removing the residue of the photoresist;
and by repeating the same process as described above, constructing a second part using a different polarity semiconductor of a N-type or P-type from said first part which has a shape wherein the P-type and N-type are arranged alternatively when assembled facing to the first part;
then, reversing said second part by 180 degree, mating to the first part,
and bonding both parts together.

The embodiment 1-9 according to the invention is a method for manufacturing a thermoelectric module wherein a dry film is adhered replacing a photoresist then exposed to and developed to make a pre-designed pattern.

The embodiment 1-10 according to the invention is a method for manufacturing a thermoelectric module wherein a dielectric substance is fabricated on the blast stopper layer prior to coating a first photoresist to make a mask.

Furthermore, a blasting mask is fabricated as designed on the pair of P-type semiconductor and N-type semiconductor element which having an element junction metal layer on the both ends or having an element junction metal layer on the both ends where a junction layer added thereon, and by means of applying a micro blasting on one end, and next for another end from the upper and lower side, it is able to grind an element junction metal layer·element or a junction layer·element junction metal layer·element where the mask removed.

Consequently, it is identified that any arbitrary shape of thermoelectric module can be manufactured in very short processing time. Furthermore, by narrowing the space between semiconductor elements, a thermoelectric module can be made in miniature or the arrangement of elements cab be mounted in higher density.

This invention is based on the results of the research mentioned above and the embodiment 2-1 of an thermoelectric module according to the invention is a thermoelectric module comprises a plurality of [symbol] -shaped elements consisting of a pair of P-type semiconductor element and N-type semiconductor element which are electrically connected in series through said electric circuit metal layers and said bonding layers, which including:
two insulating substrates which are positioned face to face;
electric circuit metal layers fabricated respectively on the surfaces of said insulating substrates;
bonding layers fabricated respectively on the electric circuit metal layers; and
a plurality of pairs of P-type semiconductor element and N-type semiconductor element formed by a micro blasting applied from the both ends, which are fabricated on said bonding layers and have respective bonding metal layers on both sides thereof.

The embodiment 2-2 according to the invention is a thermoelectric module comprises a plurality of [symbol] shape elements consisting of a pair of P-type semiconductor element and N-type semiconductor element which are electrically connected in series through said electric circuit metal layers, which including:
two insulating substrates which are positioned face to face;
electric circuit metal layers fabricated respectively on the surfaces of said insulating substrates;
a plurality of pairs of P-type semiconductor and N-type semiconductor formed by a micro blasting applied from the both ends, which are fabricated on said electric circuit metal layers and have respective bonding metal layers on both sides and the bonding layers further fabricated respectively thereon.

The embodiment 2-3 of a thermoelectric module according to the invention is a thermoelectric module wherein the P-type semiconductor and N-type semiconductor are made of a P-type and N-type Bi—Te group semiconductor respectively.

The embodiment 2-4 according to the invention is a thermoelectric module wherein the electric circuit metal layer is made of a metal selected from a group consisting of Cu, Cr, Ni, Ti, Al, Au and Si or an alloy thereof, or a laminated layer of thereof.

The embodiment 2-5 according to the invention is a thermoelectric module wherein the element junction metal layer is made of a chemical element selected from a group consisting of Cu, Ti, Cr, W, Mo, Pt, Zr, Ni, Si, Pd and C or an alloy thereof, or a laminated layer thereof.

The embodiment 2-6 according to the invention is a thermoelectric module wherein the insulating substrate is made of an insulating nitride compound, oxide compound including at least one chemical element selected from a group consisting of Al, Ti, Zr, diamond and C, or an insulated carbonized material.

The embodiment 2-7 according to the invention is a thermoelectric module wherein the junction layer is made of a chemical element selected from a group consisting of Au, Ag, Ge, In, P, Si, Sn, Sb, Pb, Bi, Zn and Cu or an alloy thereof.

The embodiment 2-8 according to the invention is a thermoelectric module wherein a space formed by a plurality of [symbol] -shaped elements is filled with a insulating synthetic resin.

The embodiment 2-9 according to the invention is a method for manufacturing a thermoelectric module comprising a plurality of [symbol] -shaped elements consist of a pair of P-type and N-type semiconductor element which are sandwiched between two insulating substrates and electrically connected in series, and said method comprises the steps of:
preparing the insulating substrate having the electric circuit metal layer formed on one side, and a plate type N-type semiconductor element and P-type semiconductor element having bonding metal layers fabricated respectively on the upper and lower side thereof;
forming a bonding layer on said electric circuit metal layer or said bonding metal layer;
applying a micro blasting on one side of said plate type N-type or P-type semiconductor;
bonding a blasted surface to said insulating substrate;
further applying a micro blasting on another side; and
combining the P-type semiconductor and N-type semiconductor thus prepared which are bonded to the insulating substrate.

The embodiment 2-10 of according to the invention is a method for manufacturing a thermoelectric module comprising a plurality of [symbol] -shaped elements consisting of combined N-type semiconductor element having the element side junction metal layer and the junction metal layer on both sides with the P-type semiconductor element, and having connected electrically in series via the electric circuit metal layer, including
a top and a bottom tow insulating substrates,
an electric circuit metal layer fabricated on each side of the substrates aligned opposite,
a junction layer fabricated adjacent to the electric circuit metal layer,
an bonding metal layer fabricated adjacent to the junction layer,
and
a pair of P-type and N-type semiconductor formed between the element side junction metal layers, said method comprises the step of:
   forming a junction layer on the element junction metal layer;
   forming a blasting mask on one side of the junction layer;
   applying a blasting process dipping until the pre-designed depth by a micro blasting on one side of the plate of N-type or the P-type semiconductor which having a blasting mask fabricated thereon;
   removing the blasting mask;
   bonding the N-type or P-type semiconductor plate which the blasting process applied wherein the processed junction layer positions oppositely to the electric circuit metal layer of the insulating substrate;
   forming a blasting mask on another junction layer which the blasting process has not applied;
   applying a micro blasting to another side of the N-type or P-type semiconductor plate which the blasting mask has fabricated;
   making an about pillar shape elements separately which the electric circuit metal layer and the junction layer are fabricated on the both sides;
   removing the blasting mask.

The embodiment 2-11 according to the invention is a method for manufacturing a thermoelectric module consisting of a plurality of [symbol] -shaped elements wherein the P-type and N-type semiconductor where the element junction metal layer and the junction layer are fabricated on the substrate via he electric circuit metal layer, are electrically connected in series by combining the P-type semiconductor and N-type semiconductor together as being sandwiched between the two top and bottom insulating substrates, the method comprising the step of:
forming a junction layer on the electric circuit metal layer in the pattern corresponding to the electric circuit metal layer;
forming a blasting mask on the one side of the electric circuit metal layer;
applying a blasting process dipping until the pre-designed depth by a micro blasting to the one side of the plate of N-type or the P-type semiconductor which having a blasting mask fabricated thereon;
removing the blasting mask;
bonding the N-type or P-type semiconductor plate which the blasting process applied wherein the processed electric circuit metal layer positions oppositely to the junction layer of the insulating substrate;
forming a blasting mask on another junction layer which the blasting process has not applied;
applying a micro blasting to another side of the N-type or P-type semiconductor plate which the blasting mask has fabricated;
making an about pillar shape elements separated which the electric circuit metal layer is fabricated on the both sides;
removing the blasting mask.

The embodiment 3-1 according to the invention is a method for processing a wafer comprises the steps of:
covering a surface of a wafer to be processed with a mask material in a pre-designed pattern;
placing a supporting part of which a portion corresponding to the mask material is made of a convex part and a remaining portion being a concaved part on a back side of said wafer to be processed; and
blasting an abrasive to said wafer to be processed which is covered by said mask material to perforate an area of said concaved part.

The embodiment 3-2 according to the invention is a method for processing a substrate wherein a side wall processed by said blasting is formed to be substantially perpendicular.

The embodiment 3-3 according to the invention is a method for processing a substrate further comprising the step of fixing said wafer to be processed to said supporting part by a fixing means.

The embodiment 3-4 according to the invention is a method for processing a substrate comprises the step of slicing the processed substrate into a plurality of pieces by the perforating the part to be removed as surrounded by the part to remain.

The embodiment 3-5 according to the invention is a method for processing a substrate wherein the pre-designed shape of the masking material is made corresponding to the object shape of the processed substrate and the masking material is made in the pre-designed shape by carrying an exposure and developing process to the film-like mask which is adhered on the processed substrate.

The embodiment 3-6 according to the invention is a method for manufacturing a thermoelectric module comprises the steps of:
placing a thermoelectric semiconductor wafer being contact to a surface of convex parts on a supporting part wherein the supporting part has a plurality of convex parts arranged on a flat plate corresponding to an object shape of the thermoelectric semiconductor wafer to be processed;
placing a film like material on said thermoelectric semiconductor wafer;
exposing and developing the film like material and forming a predetermined shape of masking material corresponding to said shape to be processed of said thermoelectric semiconductor wafer;
blasting an abrasive on the thermoelectric semiconductor wafer which is covered by said masking material to perforate in concave part which surrounds the convex part;
forming an arranged plurality of pillars comprising said convex part, thermoelectric semiconductor element and masking material; and
removing said masking material.

The embodiment 3-7 according to the invention is a method for manufacturing a thermoelectric module comprising the step of bonding the thermoelectric semiconductor element which the masking material is removed off with the substrate having the electric circuit metal layer wherein the arrangement of the semiconductor elements on the surface of the convex part of the supporting part on the substrate is a removal and temporary fixing.

The embodiment 3-8 according to the invention is a method for manufacturing a thermoelectric module wherein
the convex part is made by a an electric circuit metal layer,
the supporting part is a part of the substrate having the electric circuit metal layer, and
the arrangement of the thermoelectric semiconductor substrate to the surface of the convex part is a final configuration.

The embodiment 3-9 according to the invention is a method for manufacturing a thermoelectric module wherein the perforation process makes a side wall to be about perpendicular plane.

The embodiment 3-10 according to the invention is a method for manufacturing a thermoelectric module wherein the thermoelectric semiconductor substrate is made of the P-type and N-type the thermoelectric semiconductor substrates and the P-type and N-type the thermoelectric semiconductor substrates are arranged alternatively in vertical and horizontal directions when assembling.

The embodiment 3-11 according to the invention is a method for manufacturing a thermoelectric module further comprising the step of transferring said thermoelectric semiconductor elements to the transferring part after the masking material removed, wherein the transferring of said thermoelectric semiconductor element to said transferring part moves said P-type thermoelectric semiconductor elements and N-type thermoelectric semiconductor elements to the same transferring part or different transferring part respectively, consequently it forms the P—N elements arrangement.

The embodiment 3-12 according to the invention is a method for manufacturing a thermoelectric module wherein bonding the thermoelectric semiconductor element to the substrate with the electric circuit metal layer is carried out to make the P—N element arrangement being sandwiched by the substrates.

The embodiment 3-13 according to the invention is a supporting substrate wherein a wafer to be processed by blasting an abrasive is positioned thereon, and including a plurality of convex parts and a plurality of concave parts which forms circumference of said convex part which arranged corresponding to a pre-designed pattern of said wafer to be processed.

The embodiment 3-14 according to the invention is a substrate supporting part wherein the processed substrate is made of a P-type or N-type thermoelectric semiconductor element and its convex parts are fabricated on the plane surface of the slate material.

Furthermore, it is identified that it is possible to prevent an excess bonding material which is forced out by pressure when bonding an electrode of a micro element and the electric circuit metal layer of the substrate via the bonding layer by means of constructing a container within the electric circuit metal layer of the substrate to absorb it, and hence it can provide a module consisting of micro elements with high density mounting capability of the narrow pitch. Also, it is identified that it is possible to reduce the manufacturing cost as the tight height control is not needed but only needs applying a predetermined heat and pressure on the micro elements, by preparing a means of adjusting a height of the protrude and adding the container.

The invention is based on the research result as above and the embodiment 4-1 according to the invention is a module including a plurality of micro elements mounted at high density on a substrate wherein electrodes of said micro element and corresponding electric circuit metal layer of said substrate are bonded via bonding layer, and said electric circuit metal layer of said substrate has a container portion to absorb an excess bonding material which is used to form said bonding layer when it is forced out by pressure.

The embodiment 4-2 according to the invention is a module including a micro element wherein said electric circuit metal layer consists of a flat plate and a protruding portion, said protruding portion is formed on the side facing to said micro element, and said container consists of said protruding portion, said flat plate and said electrode of said micro element.

The embodiment 4-3 according to the invention is a module including a micro element wherein the bonding material forming the bonding layer is made of an alloy of at least two elements selected from a group consisting of Gold (Au), Silver(Ag), Germanium (Ge), Indium (In), Phosphorus (P), Tin (Sn), Antimony (Sb), Lead (Pb), Cupper (Cu) or Bismuth (Bi).

The embodiment 4-4 according to the invention is a module including a micro element wherein a volume of the bonding material used for forming the bonding layer has a smaller than or equal to a value subtracting a volume of the protruding portion from a volume induced an area of the electric circuit metal layer of the substrate multiplied by a height of the protruding portion.

The embodiment 4-5 according to the invention is a module including a micro element wherein the protruding portion is made of a metal having same conductivity as the electric circuit metal layer or the electrode of the micro element or a metal of different conductivity.

The embodiment 4-6 according to the invention is a method for narrow pitch bonding of a plurality micro elements at high density on a substrate comprises the steps of:
providing a protruding portion on the electric circuit metal layer of said substrate corresponding to the electrode of said micro element,
placing a suitable amount of bonding material to form the bonding layer between said electrode of said micro element and said protruding portion,
pressing said micro element towards-said electric circuit metal layer of said substrate through said bonding material and containing an excess part of said bonding material in the space made by said protrude and said electrode of said micro element, and
forming said bonding layer.

The embodiment 4-7 according to the invention is a method for a narrow pitch bonding of the micro element comprising the step of determining the amount of the bonding material so that the excess part of the bonding material does not occur to swell out from the circumference of the micro elements and the electric circuit metal layer corresponding thereto.

The embodiment 4-8 according to the invention is a method for a narrow pitch bonding of the micro element wherein the electrode of the micro element is forced to push towards the protruding portion so as not to form a gap between the electrode of the micro element and the protruding portion.

The embodiment 4-9 according to the invention is a method for a narrow pitch bonding of the micro element wherein the electrode of the micro element is forced to push towards the protruding portion, so that the bonding layer is formed between the electrode of the micro element and the top surface of the protruding portion and between the electrode of the micro element and the circumference of the protruding portion.

The embodiment 4-10 according to the invention is a method for a narrow pitch bonding of the micro element wherein a volume of the bonding material forming the bonding layer is less than or equal to a value subtracting a volume of the protruding portion from a volume induced an area of the electric circuit metal layer of the substrate multiplied by a height of the protruding portion.

When the surface of the substrate is covered partially by the masking material and carrying out a blasting an abrasive to slice a plurality of the elements by either method of:
blasting where the direction is not vertical from the top side but blasting an abrasive to the side of the substrate directly or indirectly where the masking material has been covered; or
forming another layer of material on at least the masking side of the substrate, whose grinding speed is slower for blasting than the material of the substrate;
   in order to make the cross sectional area of the side of the element being smaller than the area of smaller side from the top or bottom of the element, and hence the difference in the area between the top or bottom of the element is minimized.

Consequently, it is identified that the method for high density mounting is feasible.

The invention is based on the research result as above and the embodiment 5-1 is a method for processing a wafer comprises the steps of:

covering a surface of the wafer to be processed with a masking material of a pre-designed pattern corresponding to an object shape of a plurality of elements; and

blasting an abrasive on said wafer to be processed which has said masking material covered so that at least one plane of the cross sectional areas which parallel to said substrate of said element is made smaller than a smaller area of either top or bottom surface of said element.

The embodiment 5-2 according to the invention is a method for processing a substrate comprising the step of blasting an abrasive to the side of the element at predetermined angle.

The embodiment 5-3 according to the invention is a method for processing a substrate comprising the step of blasting an abrasive to the part and using the abrasive flung back from the part and secondary blasting to the side of the element.

The embodiment 5-4 according to the invention is a method for processing a substrate wherein a different material layer is formed on at least one surface of said wafer which is covered with the masking material, and said different material layer is made of a material which is processed slower by the blasting abrasion than said wafer.

The embodiment 5-5 according to the invention is a method for processing a substrate wherein the different material layer is made of a metal layer selected from a group consisting of Cu, Ni, Cr, Ti, Pt, Pd, W, Mo, Zr, Al, Ag and Au or alloy layer from thereof.

The embodiment 5-6 according to the invention is a method for manufacturing a thermoelectric module comprising a plurality of [symbol] -shaped elements consist of a pair of P-type and N-type semiconductor element which are electrically connected in series via an electric circuit metal layer and a bonding layer, said method comprises the steps of:
covering a surface of a P-type or N-type semiconductor wafer with a masking material of a pre-designed pattern corresponding to an object shape of a plurality of elements;
blasting an abrasive on said P-type or N-type semiconductor wafer which has said masking material covered so that at least one plane of cross sectional areas which are parallel to a top or bottom surface of said element is made smaller than a smaller area of either top or bottom surface of said element;
assembling the P-type and N-type thermoelectric semiconductor elements;
bonding the wafers with the electric circuit metal layer to both surfaces of said assembled P-type and N-type semiconductor elements as sandwiched therebetween.

The embodiment 5-7 according to the invention is a method for manufacturing a thermoelectric module comprises a method of assembling the top surface of the P-type and the bottom surface of the N-type being positioned on the same substrate with electrodes, and the bottom surface of the P-type and the top surface of the N-type positioned same respectively, when combining the P-type and N-type thermoelectric semiconductor,

The embodiment 5-8 according to the invention is a thermoelectric module comprises a plurality of [symbol] -shaped elements consist of a plurality pairs of P-type thermoelectric semiconductor element and N-type thermoelectric semiconductor element which are electrically connected in series through an electric circuit metal layer and a bonding layer, which including:
two insulating substrates which are positioned face to face;
an electric circuit metal layer fabricated respectively on a surface of said insulating substrate;
a bonding layer fabricated on said electric circuit metal layer; a plurality of pairs of P-type and N-type semiconductor element fabricated on said bonding wherein at least one plane of cross sectional areas which are parallel to a top or bottom surface is made smaller than a smaller area of either top or bottom surface.

The embodiment 5-9 according to the invention is a thermoelectric element comprising; the top surface of the P-type and the bottom surface of the N-type thermoelectric semiconductor element, and the bottom surface of the P-type thermoelectric semiconductor element and the top surface of the N-type thermoelectric semiconductor element are respectively positioned on the substrate including the electric circuit metal layer.

The embodiment 6-1 according to the invention is a method for manufacturing a thermoelectric module comprising a plurality of [symbol] -shaped elements consist of a pair of P-type and N-type semiconductor element which are sandwiched between two insulating substrates and electrically connected in series, said method comprises the steps of:
forming a wafer consisting of a P-type semiconductor element or N-type semiconductor element respectively which has a metal electrode fabricated on a top surface thereof and a metal electrode/bonding material on a bottom surface thereof;
fixing said wafer consists of a P-type semiconductor element or N-type semiconductor element as said bottom side being positioned on a temporary supporting part;
slicing said ware to discrete elements in a pre-designed dimensions;
preparing an insulating substrate having the electric circuit metal layer on one side with a protruding portion fabricated further thereon;
forming a bonding material as a bonding layer on said protruding portion corresponding to a respective area of elements arranged on a substrate circuit pattern;
boding said bonding material of said insulating substrate to said elements which are cut on said temporary supporting part,
preparing a substrate with P-type semiconductor elements or N-type semiconductor elements mounted thereon wherein said P-type semiconductor element or N-type semiconductor element are correspondingly arranged on said substrate circuit pattern;
assembling thus prepared substrates with P-type semiconductor elements and N-type semiconductor elements mounted respectively thereon.

The embodiment 6-2 according to the invention is a method for manufacturing a thermoelectric module wherein
the bonding material fabricated on the protruding portion is bonded with the metal layer of the element bonding side which is consisting of the metal electrode,
the pattern of the elements of the substrate is separated from the temporary supporting part and transferred to the insulating substrate, and
other elements remains on the temporary supporting part.

The embodiment 6-3 according to the invention is a method for manufacturing a thermoelectric module wherein

The elements consisting of a P-type semiconductor elements or N-type semiconductor elements are arranged in a zigzag pattern on the P-type semiconductor mounting substrate or N-type semiconductor mounting substrate respectively, and when combining the P type semiconductor mounting substrate and N-type semiconductor mounting substrate, the P-type semiconductor elements and N-type semiconductor elements are arranged alternatively in the horizontal and vertical direction.

The embodiment 6-4 according to the invention is a method for manufacturing a thermoelectric module wherein
the bonding metal layer, which consisting of the metal electrodes/bonding material and fabricated under the element, is bonded on each protruding portion, which has no bonding material as a bonding layer formed thereon, when assembling the P-type semiconductor mounting substrate with the N-type semiconductor mounting substrate.

The embodiment 6-5 according to the invention is a method for manufacturing a thermoelectric module wherein the remaining elements on the temporary supporting part are consisting of the elements on the substrate circuit pattern including P-type semiconductor elements and N-type semiconductor elements,
the bonding material formed on the protruding portion is joined with the element bonding side metal layer which is made of the metal electrode,
and separated apart from the temporary supporting part and transferred to the insulating substrate.

The embodiment 6-6 according to the invention is a thermoelectric module comprising electric circuit metal layers respectively fabricated on each surface of the substrates aligned opposite, bonding layers including a protruding portion fabricated on the electric circuit metal layer, a metal electrode on the top surface and a metal electrode/bonding material on the bottom surface fabricated adjacent to said bonding layer, a plurality of [symbol] -shaped elements consisting of a P-type semiconductor element and N-type semiconductor element electrically connected in series as sandwiched by two insulating substrates, which is manufactured by the steps of:
fabricating an insulating substrate having an electric circuit metal layer on one side and a protruding portion further on the electric circuit metal layer;
fabricating a bonding material as a bonding layer on said protruding portions corresponding to elements arranged on a substrate circuit pattern;
fabricating a wafer consisting of a P type semiconductor element or N type semiconductor element respectively which has a metal electrode formed on a top surface and a element bonding surface metal layer comprising a metal electrode/bonding material on a bottom surface, a discrete element being made in a dimension as pre-designed from said wafer;
assembling together a P-type semiconductor element mounting substrate and a N-type semiconductor element mounting substrate thus prepared wherein said bonding material of said insulating substrate is bonded to said elements, and the elements consisting of said P-type semiconductor element or N-type semiconductor element are arranged in the area for the elements on the substrate circuit pattern.

### BRIEF DESCRIPTION OF THE DRAWINGS

FIG. 1-1 shows a construction of a thermoelectric module in accordance with the invention;

FIG. 1-2 shows an insulating substrate to fabricate a module of the invention;

FIG. 1-3 shows an interim processed part in which a bonding layer and a blast stopper are added on the substrate;

FIG. 1-4 shows a part in which a photoresist is coated thereon and exposed to a light to open a window in the pre-designed area;

FIG. 1-5 shows a part which the blast stopper and the bonding layer in the window area is removed by etching and the photoresist removed next;

FIG. 1-6 shows a part which a bonding layer is coated on the thermoelectric semiconductor element;

FIG. 1-7 shows a configuration wherein the thermoelectric semiconductor FIG. 1-6 is turned upside down and bonded on the part as shown in FIG. 1-5;

FIG. 1-8 shows a interim processed part which the bonding layer is added on the top surface of the part as shown in FIG. 1-5;

FIG. 1-9 shows a configuration wherein a photoresist is coated on the top surface of the part as shown in FIG. 1-8;

FIG. 1-10 shows a configuration wherein the photoresist is fabricated in the predetermined mask pattern;

FIG. 1-11 shows a configuration wherein the only area where the photoresist is removed is cut by a micro blasting on the part as shown in FIG. 1-10;

FIG. 1-12 shows a configuration wherein the photoresist is removed on the part as shown in FIG. 1-11;

FIG. 1-13 shows a construction using another polarity thermoelectric semiconductor with same process as FIG. 1-2 through FIG. 1-12;

FIG. 1-14 shows a construction wherein the interim processed part shown in FIG. 1-12 is jointed to the part shown in FIG. 1-13 after rotating 180 degree;

FIG. 1-15 shows a final configuration wherein the two interim processed parts are bonded by the bonding layer together;

FIG. 1-16 is a table listing a various material suitable for the thermoelectric module and showing the characteristics which are usable for a thermoelectric semiconductor of the invention;

FIG. 2-1 is an explanatory fragmentary cross section view of one embodiment of the thermoelectric module in accordance with the invention;

FIG. 2-2 is an explanatory fragmentary cross section view of another embodiment of the thermoelectric module in accordance with the invention;

FIG. 2-3 is showing a shape of the semiconductor (including an element side bonding metal layer, or an element side bonding metal layer and bonding layer) which is processed by a micro blasting from one side (One side blasting);

FIG. 2-4 is showing a shape of the semiconductor (including a bonding metal layer, or a bonding metal layer and a bonding layer) which is processed by a micro blasting from both side (Double side blasting);

FIG. 2-5 is showing a substrate 2-2 wherein an electric circuit metal layer is fabricated thereon;

FIG. 2-6 is an explanatory drawing of the configuration wherein a bonding metal layer is fabricated on the both ends of the element (for example, N-type semiconductor element) and a bonding layer is fabricated on it continuosly, then a blasting mask is fabricated with a pre-designed pattern on one side of the bonding layer;

FIG. 2-7 is an explanatory drawing of the configuration wherein a bonding metal layer, a bonding metal layer and element is ground and removed off excluding the area of the blasting mask remains in the pre-designed pattern;

FIG. 2-8 is an explanatory drawing of the configuration wherein after rotating an element (+a bonding layer+an bonding metal layer) having a blasting to one side bonding metal layer thereof by 180 degree, the bonding layer of the processed side is positioned opposite and bonded to the substrate which has the electric circuit metal layer;

FIG. 2-9 is an explanatory drawing of the configuration wherein a blasting mask is fabricated as pre-designed pattern on the bonding layer that is not processed of the blasting;

FIG. 2-10 is an explanatory drawing of the configuration wherein a N-type element having a blasting mask processed on both sides is fabricated on the substrate; FIG. 2-11 is an explanatory drawing of the configuration wherein a P-type element having a blasting mask processed on both sides is fabricated on the substrate:

FIG. 2-12 is an explanatory drawing of the configuration wherein the substrate having a P-type element with a blasting mask processed on both sides and the substrate having a N-type element with a blasting mask processed on both sides are assembled together;

FIG. 2-13 shows one embodiment of the thermoelectric module in accordance with the invention;

FIG. 2-14 shows a substrate on which an electric circuit metal layer is fabricated wherein a bonding layer is fabricated thereon;

FIG. 2-15 is an explanatory drawing of the configuration wherein a bonding metal layer is fabricated on the both ends of the element (for example, N-type semiconductor element) and a blasting mask is fabricated on one side of the bonding metal layer as pre-designed pattern;

FIG. 2-16 is an explanatory drawing of the configuration wherein a bonding metal layer and element is ground and removed excluding the area of the blasting mask remains as pre-designed pattern;

FIG. 2-17 is an explanatory drawing of the configuration wherein after rotating an element (+an bonding metal layer) having a blasting processed to one side by 180 degree, the element bonding layer of processed side is positioned opposite and bonded to the substrate which having an electric circuit metal layer fabricated further the bonding layer is fabricated thereon;

FIG. 2-18 is an explanatory drawing of the configuration wherein a blasting mask is fabricated as pre-designed pattern on the element bonding layer which is not processed of the blasting;

FIG. 2-19 is an explanatory drawing of the configuration wherein a N-type element having a blasting processed on both sides is fabricated on the substrate;

FIG. 2-20 is an explanatory drawing of the configuration wherein a P-type element having a blasting processed on both sides is fabricated on the substrate;

FIG. 2-21 shows another embodiment of the thermoelectric module in accordance with the invention;

FIG. 2-22 is an explanatory drawing of the configuration wherein a blasting mask is fabricated on one side as pre-designed pattern and a blasting process is applied, and assembling the processed bonding layer with the electric circuit metal layer, furthermore another blasting mask is fabricated on another bonding layer in different pattern;

FIG. 2-23 is an explanatory drawing of the process of the blasting to another side;

FIG. 2-24 is an explanatory drawing of pattern of the blasting mask;

FIG. 3-1 shows a brief method for processing the substrate of the invention;

FIG. 3-2 is one of explanatory cross sectional view of a configuration which a substrate is processed by a conventional method having a coating on a surface of the substrate by a masking material and placing a substrate supporting part under the substrate;

FIG. 3-3 is one of cross sectional view showing the fundamental method for processing the substrate in accordance with the invention;

FIG. 3-4 is an explanatory cross sectional view showing the conventional fundamental method for processing the substrate;

FIG. 3-5 shows a method for processing a thermoelectric module in accordance with the invention;

FIG. 3-6 shows one example of pattern of the convex part of the mask and the substrate supporting part;

FIG. 3-7 shows arrangement pattern of the P-type thermoelectric semiconductor and N-type thermoelectric semiconductor which transferred from a secondary fixing jig;

FIG. 4-1 shows one embodiment of the module having a micro element in accordance with the invention;

FIG. 4-2 shows another embodiment of the module having a micro element in accordance with the invention;

FIG. 4-3 shows a protruding portion of the electric circuit metal layer and a bonding layer;

FIG. 4-3A is a perspective view showing one embodiment of a protruding portion of the electric circuit metal layer and the bonding layer; FIG. 4-3B is a cross sectional view showing a protruding portion of the electric circuit metal layer and the bonding layer. FIG. 4-3C is a perspective view showing another embodiment of a protruding portion of the electric circuit metal layer and the bonding layer; FIG. 4-3D is a perspective view showing a different embodiment of a protruding portion of the electric circuit metal layer and the bonding layer;

FIG. 4-4 is an explanatory drawing showing a conventional bonding between an electric circuit metal layer on the substrate and electrodes of a fine electric element/fine semiconductor element;

FIG. 4-5 is an explanatory drawing showing another conventional bonding between an electric circuit metal layer on the substrate and electrodes of a fine electric element/fine semiconductor element;

FIG. 5-1 is a cross sectional view showing a thermoelectric semiconductor element processed by the method for the substrate in accordance with the invention;

FIG. 5-2 is an explanatory drawing showing a method of blasting an abrasive in the process of the substrate in accordance with the invention;

FIG. 5-3 is an explanatory drawing showing a method of blasting an abrasive in the processing the substrate in accordance with the invention;

FIG. 5-4 is a cross sectional view showing an element when a sand blasting has finishsd by the method according to the invention;

FIG. 5-5 is a schematic cross sectional view showing a thermoelectric semiconductor element wherein a P-type and a N-type element are connected alternatively in series;

FIG. 5-6 shows a conventional method of sand blasting for the substrate;

FIG. 5-7 is a schematic perspective view showing an element formed by a sand blasting of the conventional method for the substrate;

FIG. 5-8 is a cross sectional view taken in line A-A′ in FIG. 5-7;

FIG. 5-9 is a cross sectional view showing an element processed by a conventional method which is not forming a vent part;

FIG. 5-10 shows a thermoelectric element by assembling the elements in FIG. 9 in an occlusion of PN bonding;

FIG. 6-1 shows a wafer comprising a P-type semiconductor element or a N-type semiconductor element wherein a metal electrode on the top surface and a bonding metal layer consisting of an electrode/bonding material is formed on the bottom surface thereof. FIG. 6-2 shows a configuration wherein the wafer having the bonding metal layer s fabricated on both sides is fixed to the temporary fixing part;

FIG. 6-3 shows a configuration wherein the wafer is sliced into a discrete element;

FIG. 6-4 shows an insulating substrate having an electric circuit metal layer on one side wherein a protruding portion is fabricated thereon further;

FIG. 6-5 shows a configuration wherein the sliced elements are bonded to the insulating substrate having an electric circuit metal layer, a protruding portion, a bonding material, on the one side;

FIG. 6-6 is an explanatory drawing showing elements which are bonded to the substrate and an element which not bonded but remain to the temporary fixing plate;

FIG. 6-7 shows a configuration after turning upside-down the elements which transferred to the substrate by a method as shown in FIG. 6-6 as the substrate stands at lower side;

FIG. 6-8 is an explanatory drawing showing the configuration wherein a P-type semiconductor mounting substrate having a P-type semiconductor elements on the circuit pattern of the substrate and a N-type semiconductor mounting substrate having a N-type semiconductor elements are assembled together;

FIG. 6-9 shows a thermoelectric semiconductor element comprising a plurality of Π shape elements wherein P-type semiconductor element and N-type semiconductor element are electrically connected in series and sandwiched by the two insulating layers;

FIG. 6-10 shows a wafer made of a P-type semiconductor element or a N-type semiconductor element which having a bonding metal layer and a bonding layer fabricated on the upper side and lower side respectively;

FIG. 6-11 shows a configuration wherein the wafer having an bonding metal layer and a bonding layer fabricated on both sides is fixed to a temporary fixing plate;

FIG. 6-12 shows a configuration of the wafer after slicing into discrete elements; and

FIG. 6-13 shows a insulating substrate which has an electric circuit metal layer with a protruding portion fabricated further thereon.

### PREFERRED ENBODIMENTS OF THE INVENTION

Referring to the drawings, the embodiments of the invention will be described below, however the present invention is not limited to those embodiments described below but also includes any embodiments which a person skilled in the art may come to think by combination of the embodiments described here.

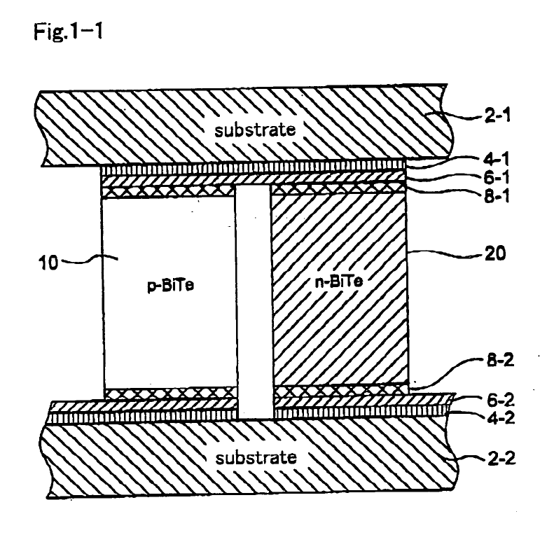

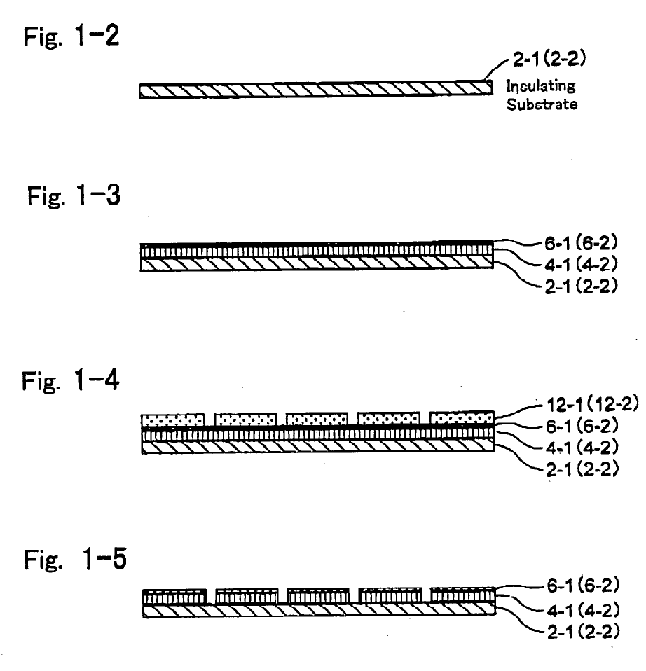

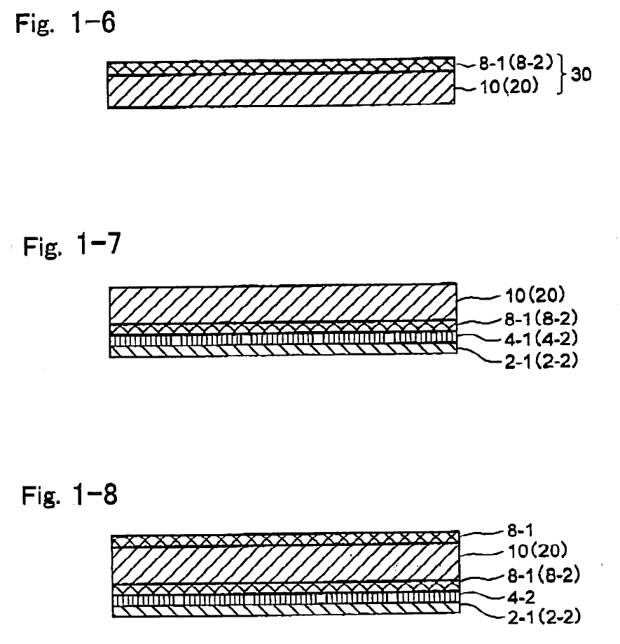

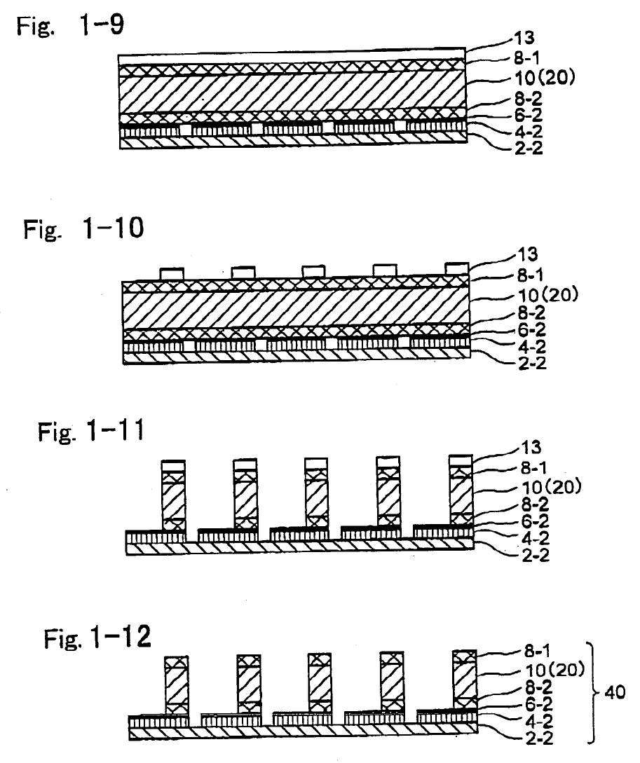

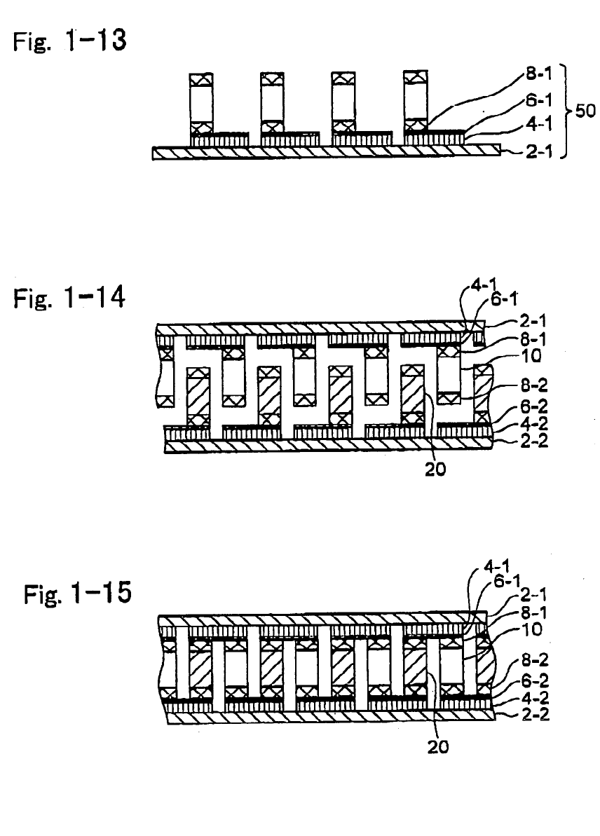

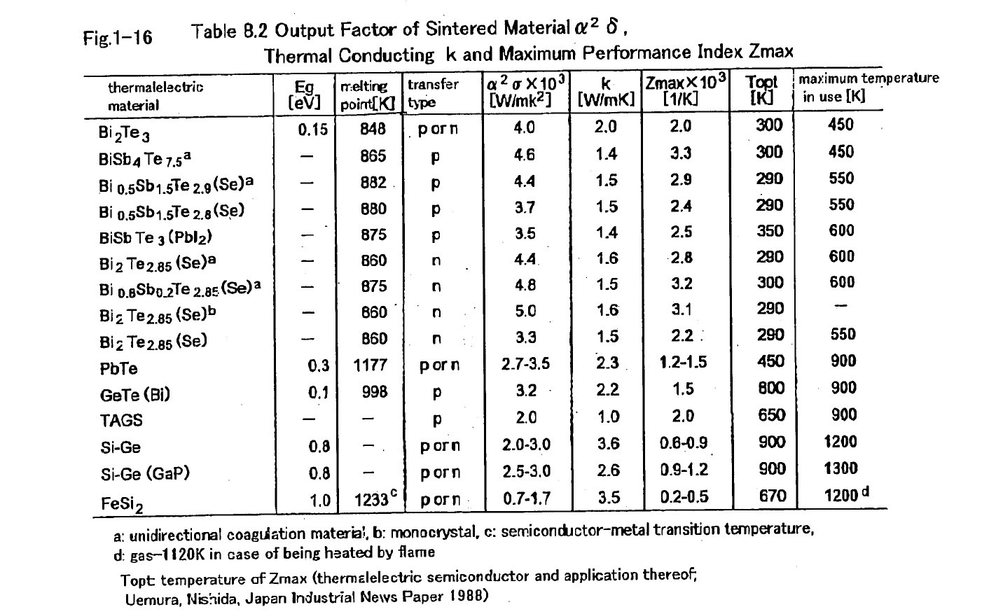

Hereinafter, referring to FIG. 1-1 through FIG. 1-15, the embodiments of the invention will be described.

FIG. 1-1 shows a schematic cross sectional view of the thermoelectric element in accordance with the invention. The P-type semiconductor 10 and the N-type semiconductor 20 are placed between the top side substrate 2-1 and the bottom side substrate 2-2 and connected to the electric circuit metal layer 4-1 via a blast stopper layer 6-1 which will be detailed later, and the P-type semiconductor 10 in the left side in the drawing is connected to the N-type semiconductor 20 in the right side, similarly the N-type semiconductor in the right side is connected further to the P-type semiconductor which is not shown in the drawing via the blast stopper layer 6-2.

As described above, the fundamental difference from a conventional thermoelectric element is that each semiconductor element is connected to the substrate via the bonding layer, the blast stopper layer and the electric circuit layer, that is a [symbol] -shaped thermoelectric element (Hereinafter, a [symbol] -shaped bonding of N-type thermoelectric element is abbreviated as a N-type element.).

A material of the electric circuit metal layer 4-1 and 4-2 is needed to function to bond the substrate and the conductive blasting stopper layer.

For the substrate 2-1 and 2-2, an insulating material of Al₂O₃, AlN, BN, Si, or an insulation coated Cu—W alloy or a insulating oxide compound or a nitride compound are typically preferred.

On the other hand, for the conductive blast stopper layer, one metal selected from a group consisting of Cu, Ti, Cr, W, Mo, Pt, Zr, Si, and C, or alloy thereof are preferred. In addition, it is preferably suitable to use a conductive nitride compound including at lease one selected from a group consisting of Al, Ti, Zr, and C, or a conductive carbide compound or a conductive oxide compound.

And the electric circuit metal layer, which joins both parts mentioned above, is made of a metal selected from a group consisting of Cu, Cr, Ni, Ti, Al, Au and Si or an alloy thereof, or laminated layers thereof which having a characteristic to adhere the substrate and the blast stopper layer.

The bonding layer 8-1, 8-2, which bonds the thermoelectric semiconductor elements 10 and 20 with the blast stopper layer, is made of a metal preferably selected from a group consisting of Au, Ag, Ge, In, P, Si, Sn, Sb, Pb, Bi and Cu or an-alloy thereof. And the bonding layer is generally made of a brazing material whose soldering point is lower than 300 degree-C. This bonding layer functions to bond the thermoelectric semiconductor element with the blast stopper layer.

Furthermore, as the P-type semiconductor and the N-type semiconductor, anything having a thermoelectric characteristic is sufficient, although a Bi—Te group semiconductor alloy is used in the preferred embodiments, it is not limited to those but any alloy having a thermoelectric characteristic is acceptable. In FIG. 1-16, some examples of the thermoelectric elements are shown.

Generally, thermoelectric element comprises a chemical compound semiconductor with thermoelectric characteristic, i.e., an intermetalic compound, and hence it is typically very fragile and difficult to process, therefore a dicing saw has been used conventionally.

Because the present invention uses a micro blasting to process, the process time is very fast. With this regards, it is a significant advantage of the present invention.

One of the embodiment according to the invention is a method for manufacturing a thermoelectric module comprising an upper and a lower insulating substrates, electric circuit metal layers bonded respectively to the surfaces of said substrate which are positioned face to face, blast stopper layers fabricated respectively on said electric circuit metal layers, bonding layers fabricated on said blast stopper layers; and a plurality of [symbol] -shaped elements consisting of a pair of the P-type semiconductor element and N-type semiconductor element which are fabricated between said bonding layers and are electrically connected in series through said upper and lower blast stopper layers, said method comprises the steps of:
preparing the substrate having the electric circuit metal layer and the blast stopper layer in a pre-designed pattern;
preparing a plate type P-type or N-type semiconductor having the bonding layer fabricated thereon;
bonding the surface of the bonding layer to the blast stopper layer fabricated on said substrate;
coating a photoresist;
forming a pre-designed pattern by an exposure;
further, by a micro blasting an abrasive, eliminating said bonding layer and said semiconductor layer of the area where the photoresist has been removed;
constructing a first part having said semiconductor layer protruded from one side of said substrate;
removing a residue of the photoresist;
and by repeating the same process as described above, constructing a second part using a different polarity semiconductor of a P-type or N-type from said first part which has a shape wherein the P-type and N-type are arranged alternatively when assembled facing to the first part;
then, reversing said second part by 180 degree, mating to the first part and bonding both parts together.

Hereinafter, a method of manufacturing a thermoelectric module including the thermoelectric element will be described referring to FIG. 1-2 through FIG. 1-15.

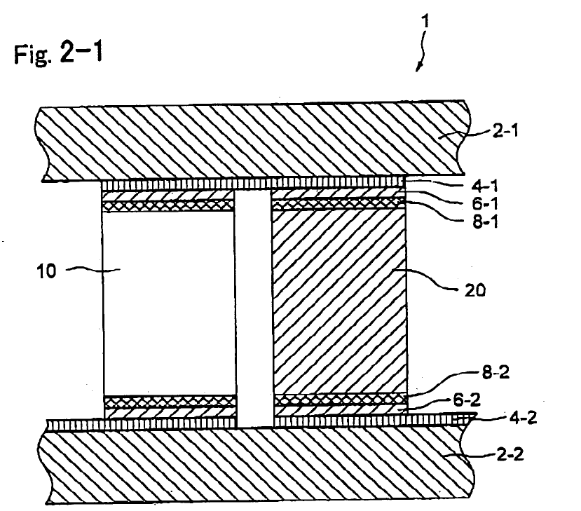

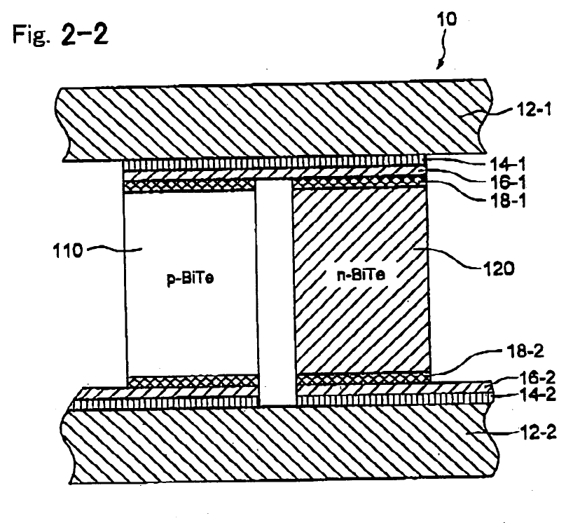

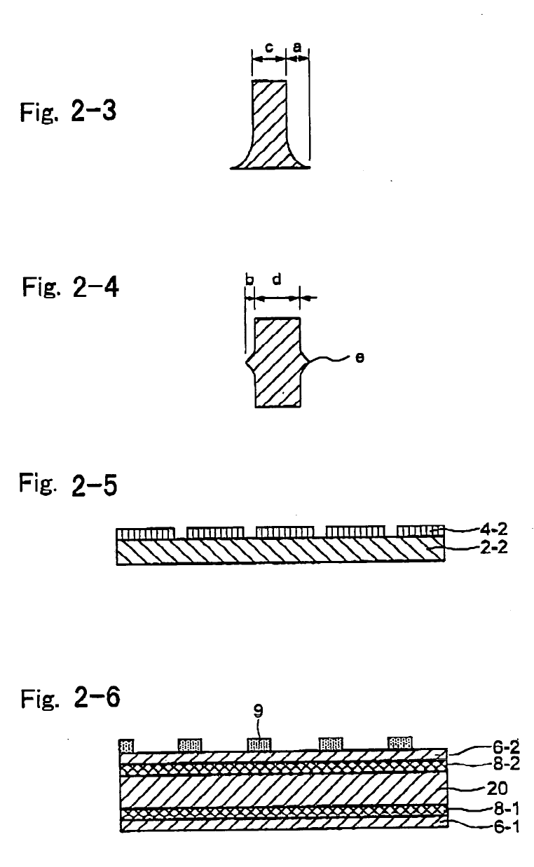

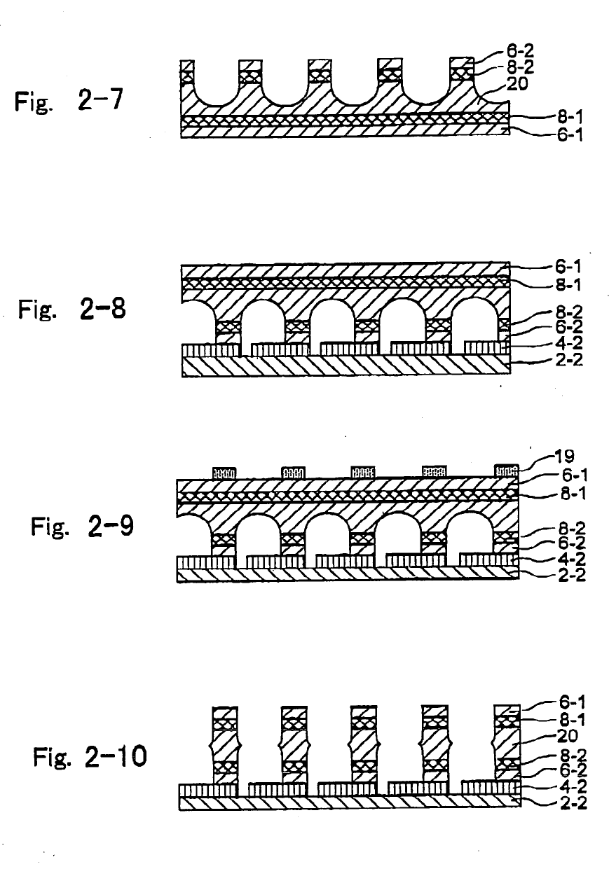

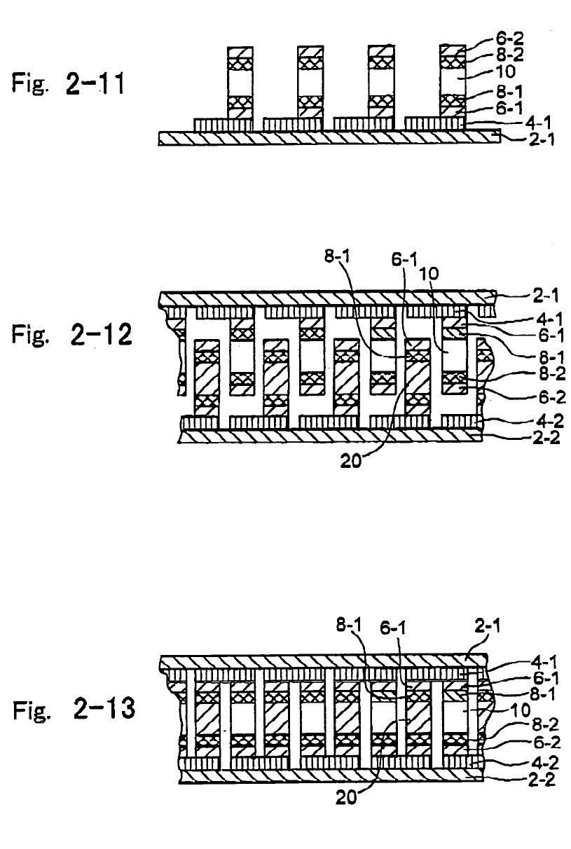

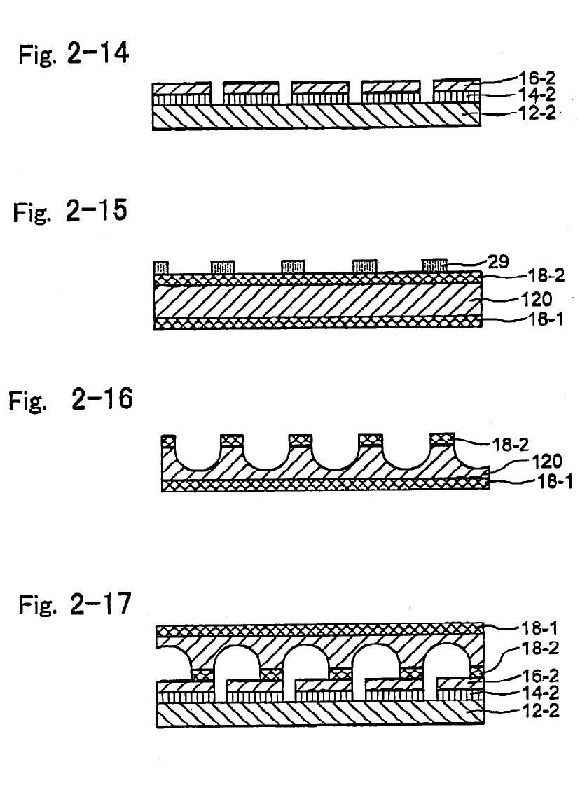

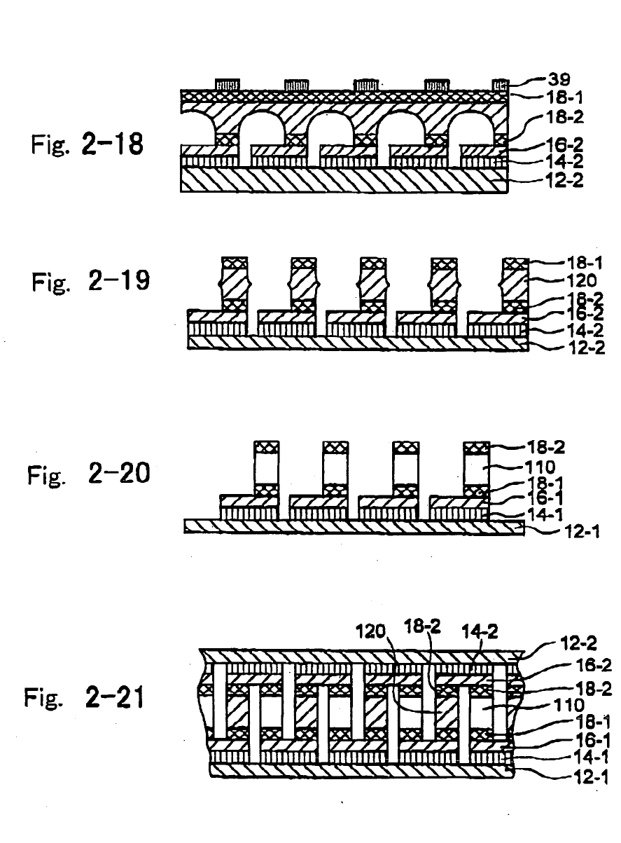

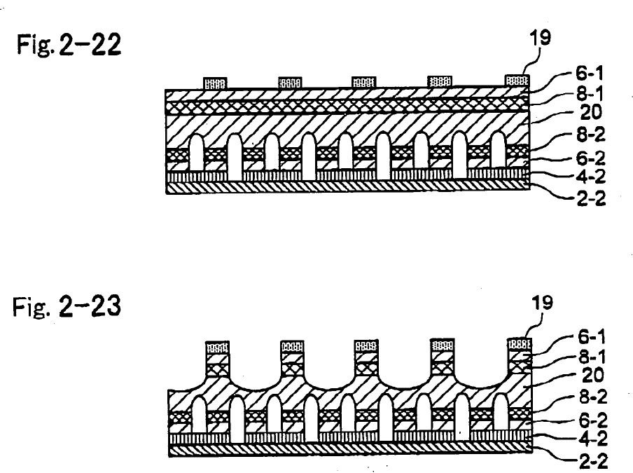

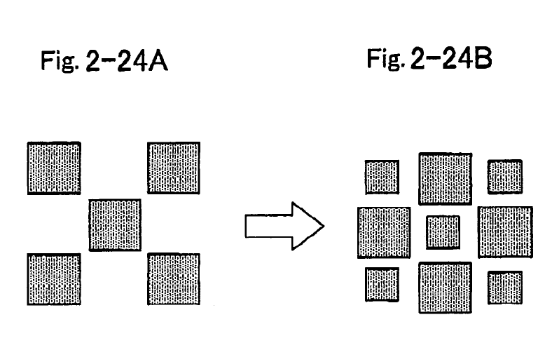

FIG. 1-2 shows namely the substrate 2-1 or 2-2. FIG. 1-3 shows the substrate which has the electric circuit metal layer and the blast stopper layer on the insulating substrate. The electric circuit metal layer and the blast stopper layer are processed by a method such as wet plating, CVD, sputtering, vacuum evaporation or ion plating etc.

FIG. 1-4 shows a member having the mask with the opening window. As shown in the FIG. 1-4, a photoresist is previously coated on the blast stopper layer and exposed for opening a window in a pre-designed area.

Furthermore, it is preferable to make a dielectric substrate such as SiO₂, SiNx by an electron beam or CVD or the like, prior to a photoresist coating, and then to adhere a photoresist film or a dry film, to coat a photoresist, to open a window, to etch the dielectric substrate film, and to transfer the mask pattern to the dielectric film, in this sequence.

FIG. 1-5 shows a configuration in which the conductive blast stopper layer and the electric circuit metal layer are removed by etching, after further etching the area of the opening area.

These processes are standard methods applied for typical semiconductor manufacturing process. FIG. 1-5 shows the substrate having the electric circuit metal layer 4-1 (4-2) and the blast stopper layer 6-1 (6-2) with the window opened by the process described above.

The process described above is a method for preparing an insulating substrate having the electric circuit metal layer and the blast stopper layer in a pre-designed pattern, however it may not be limited to the process described referring to the FIG. 1-2 through FIG. 1-5, 21 (6-2), and it is possible to process it by another method which is not disclosed here.

For example, a method comprises the steps of:
(a′) forming a thin conductive film on one side of the insulating substrate by an electroless plating, sputtering or vacuum evaporation etc.;
(b′) coating a first photoresist on the thin conductive film, exposing for making it as a pre-designed pattern and opening a window by a developing process;
(c′) forming the electric circuit metal layer in the area of the opening window by an electric plating, further forming a blast stopper layer by an electric plating, and removing the first photoresist;
(d′) removing the thin conductive film by etching and separating between patterns of the electric circuit metal layer and the blast stopper layer;
   Or, the method comprises the steps of:
(a″) coating a first photoresist on the insulating substrate, exposing for making it as a pre-designed pattern and opening a window by a developing process;
(b″) forming the electric circuit metal layer in the area of the window by an electroless plating, sputtering or vacuum evaporation etc.;
further forming the blast stopper layer by an electroless plating, sputtering or vacuum evaporation etc.;
(c″) removing the first photoresist and removing the electric circuit metal layer and the blast stopper layer which are adhered on the first photoresist.

By using such methods, it is possible to prepare the insulating substrate which has an electric circuit metal layer and the blast stopper layer in a pre-designed pattern, as shown in the same manner as in FIG. 1-5.

On the other hand, using a thermoelectric semiconductor, for example Bi—Te group plate semiconductor, a material 30 is made in which a conductive bonding layer is fabricated on the wafer 10 (20), as illustrated in FIG. 1-6.

Then rotating the wafer 10 (20) and bonding it to the substrate which has been made by the process as shown in FIG. 1-5 and has the electric circuit metal layer and the blast stopper layer, as shown in FIG. 1-7.

The bonding method may be soldering or brazing. The bonding material is preferable of a chemical element selected from a group consisting of Au, Ag, Ge, In, P, Si, Sn, Sb, Pb, Bi, Zn and Cu or an alloy thereof.

Next step is making a metal bonding material 8-1 such as a solder or brazing material film on the surface of the thermoelectric semiconductor 10 (20) as illustrated in FIG. 1-8. And, making a mask 13 on the surface of the bonding material 8-1 prepared as shown in FIG. 1-8, exposing for making it as pre-designed shape and pattern, developing, etching, and making a part as illustrated in FIG. 1-10.

Next process is a very significant process in the present invention. An area excluding the area which is covered by the mask as illustrated in FIG. 1-11 is ground in very short process time, and very instantly the semiconductor layer with no masking area is cut until it reaches the etching blast layer positioned thereunder.

It is preferable to use a mask 13 made of metal film such as a dry film or Cu with a dimension of 10-100 micron thickness for blasting the thermoelectric semiconductor.

When processing this kind of shape by using a conventional method such as a dry etching, its process time is in the range of 0.1-1 hour/micron, however it can grind the 100 micron by 1 to 3 minutes with the micro blasting of the invention, its processing speed is faster as 500-5000 times. With regard, the present invention has superior advantages.

In addition, when using a dicing saw in a conventional method, it can process only straight line, but the present invention allows to make any arbitrary shape of the mask as illustrated in above FIG. 1-11, and hence it can make any arbitrary shape of the thermoelectric semiconductor. This is a further advantage.

An ultra fine micro blasting equipment on the market may be used for this micro blasting process. In this equipment, a very hard material such as corundum with diameter 3-4 micron meter is used as an abrasive. Hence, it becomes possible to cut off the width of 10-100 micron meter in a few minutes.

A mask fabricated on the semiconductor element is removed away by an etching process as illustrated in FIG. 1-12. By the process through FIG. 1-12, the first part 40 which has a P-type or N-type thermoelectric semiconductor is made. And the second part 50 which has a different polarity of the thermoelectric semiconductor is made by the same process as in FIG. 1-2 through FIG. 1-12. If the first part has a P-type thermoelectric semiconductor, the part of FIG. 1-13 will be a second part 50 made of a N-type thermoelectric semiconductor in a mirror symmetric construction. And the thermoelectric module is made by rotating the second part 50 by180 degree and assembling with the first part 40 to bond them together. Here, the final product shown in the FIG. 1-15 is made by bonding the first part and the second part through the bonding layer 8-2 as shown in the FIG. 1-14. Method of the bonding may be a soldering, brazing, silver soldering. In this embodiment, the blast stopper layer is placed on the electric circuit metal layer, but placing on the P-type or N-type semiconductor element is another alternative. Following shows the example.

It is possible to prepare the insulating substrate which has the electric circuit metal layer in a pre-designed pattern without the process of forming the blast stopper layer, by the similar manner to the previous method for making the insulating substrate which has both the electric circuit metal layer and the blast stopper layer in a pre-designed pattern. On the other hand, the blast stopper layer may be formed on the P-type or N-type plate semiconductor by the similar method as the previous example when forming the bonding layer on the P-type or N-type plate semiconductor.

And, the following processes are applicable:

(e″) bonding the P-type or N-type plate semiconductor having the blast stopper with the insulating substrate having the electric circuit metal layer in a pre-designed pattern through the bonding layer (The bonding layer may be formed on the electric circuit metal layer or on the blast stopper, or both thereof);
(f″) further, coating a second photoresist on the P-type or N-type plate semiconductor (it is acceptable in either case of the blast stopper layer or the bonding layer formed on the upper surface of the plate semiconductor as formed on the bottom surface, but the case without the forming is preferable), exposing to form a pre-designed pattern;
(g″) blasting by a micro blast for removing the part of the semiconductor layer where the photoresist is not remained, as well as at least the blast stopper layer under it.

In the above process, the blast stopper layer placed under the P-type or N-type plate semiconductor needs to be durable for working as a stopping layer to protect the electric circuit metal layer or the like until finishing a removal of the semiconductor layer, but finally it is also removed by a blasting. And when a bonding layer is placed under the blast stopper layer and in the area to be removed, this bonding layer is also finally removed by a blasting.

The unnecessary area of semiconductor layer is removed and a pre-designed shape is made before the blast stopper layer (and a bonding layer) is worn out. So, the role is achieved. In some occasions, the blast stopper layer and the bonding layer are formed also on the upper side of the P-type or N-type plate semiconductor, and this area is first removed then starts a blasting process for the semiconductor layer. Because the blast stopper layer and the bonding layer are more durable than a semiconductor layer for a blasting, it needs a longer process time but it is possible.

The purpose of forming it also on the upper surface is aiming to simplify the process of forming the blast stopper layer (and the bonding layer) by carrying out same plating process for both sides of the plate semiconductor. It will be chosen appropriately whether simplifying to form the blast stopper layer or simplifying to remove by a blasting.

Thus, the thermoelectric semiconductor module as shown in FIG. 1-1 is manufactured. Finally, the space of a thermoelectric module may be filled by a material, for example an insulating synthetic resin, so that it realizes more durable body construction.

The actual dimension of the module made here is as follows: the electric circuit metal layer is 10-1000 micron, the blast stopper layer 1-100 micron meter, the electric circuit metal layer made of a metal, for example a solder, 10-100 micron meter.

The size of the thermoelectric semiconductor is, for example, within the range from 50×50×5 to 500×500×500 micron meter of width×depth×height.

A method for forming the blast stopper layer and the electric circuit metal layer may be either wet plating, CVD, sputtering, vacuum evaporation or ion plating etc.

And a method for forming the bonding layer may be either wet plating, CVD, sputtering, vacuum evaporation or ion plating or combination thereof.

As described above, for the bonding material of soldering, a various solder metal such as Sn—Sb, Sn—Cu, Sn—Ag or Sn—Ag—Bi—Cu is suitable.

Besides Bi—Te group of semiconductor used in the embodiment, any material having a thermoelectric characteristic is acceptable and thermoelectric elements shown in the FIG. 1-16 is suitable to use.

The dimensions of the substrate of the module made here is like in the range from 1×1 mm to 20×20 mm.

In accordance with the present invention, it is possible to make a significantly narrow spacing between the P-type and N-type semiconductor element such as 10 micron meter, hence the arrangement of the thermoelectric elements is made possible in a very high area density. Finally, the space between the thermoelectric elements may be filled by a synthetic resin, for example, an epoxy resin, but it is an option to be filled.

FIG. 2-1 is an explanatory cross sectional view of one embodiment of the thermoelectric module in accordance with the invention.

The thermoelectric module 1 of the present invention comprises:
two insulating substrates 2-1, 2-2 which are positioned face to face;
the electric circuit metal layers 4-1, 4-2 fabricated respectively to the surface of the insulating substrate;
a pair of P-type semiconductor and N-type semiconductor which are fabricated on the bonding layer and having a bonding metal layer on both sides formed by a micro blasting applied from the both ends;
a plural pair of P-type semiconductor element 10 and N-type semiconductor element 20 which are positioned on the electric circuit metal layer and processed by blasting to both sides with a micro blast method, and which having the element side bonding metal layers 8-1, 8-2 fabricated on both ends thereof and the bonding layers 6-1, 6-2 further fabricated on it; and
a plurality of [symbol] -shaped elements composed from the pair of P-type semiconductor element and N-type semiconductor element are electrically connected in series through the electric circuit metal layer 4-1, 4-2.

FIG. 2-2 is an explanatory cross sectional view of another embodiment of the thermoelectric module in accordance with the invention.

The thermoelectric module 10 including a plurality of [symbol] -shaped elements composed from the pair of P-type semiconductor element 110 and N-type semiconductor element 120 which are electrically connected in series through the electric circuit metal layer 14-1, 14-2 and the bonding layers 16-1,16-2 of the present invention comprises:
two insulating substrates 12-1,12-2 which are positioned face to face;
the electric circuit metal layers 14-1, 14-2 fabricated respectively to the surface of the insulating substrate;
the bonding layers 16-1, 16-2 fabricated on the electric circuit metal layer;
a plural pair of P-type semiconductor element 110 and N-type semiconductor element 120 which are positioned on the bonding layer and processed by blasting to both sides with a micro blast method, and which having the element side bonding metal layers 18-1, 18-2 fabricated on both ends thereof.

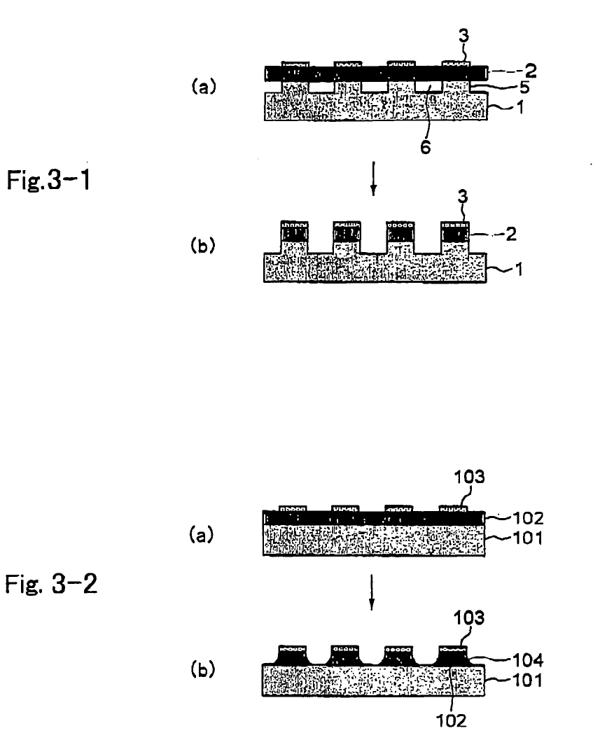

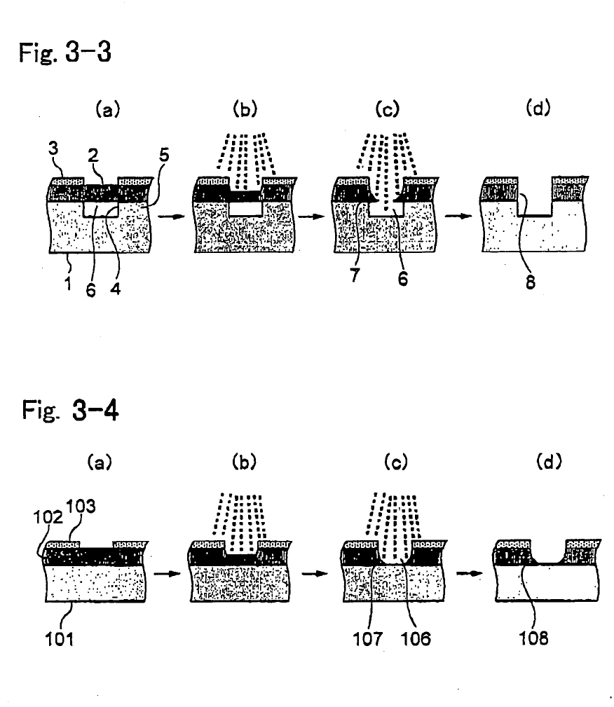

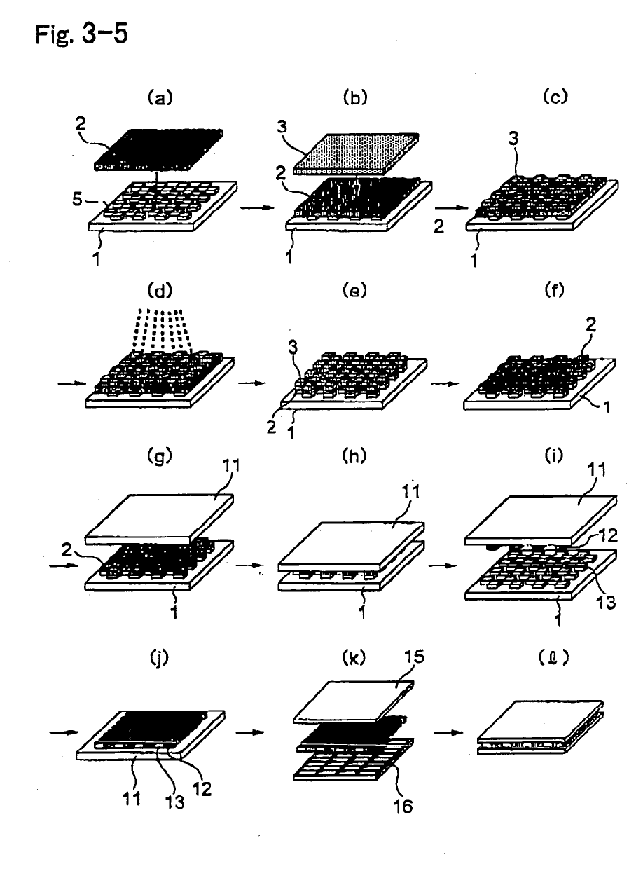

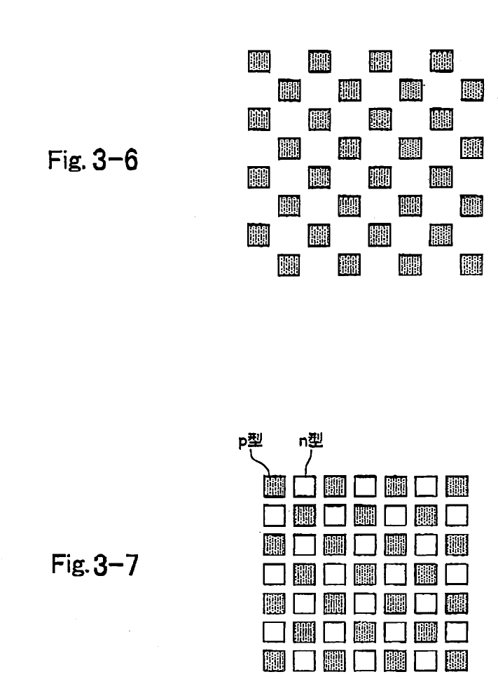

FIG. 2-3 shows a shape of the semiconductor element (including the element side bonding metal layer, or the element side bonding metal layer and the bonding layer) which is processed by a micro blasting from one side (One side blasting).

As illustrated in FIG. 2-3, in case of One side blasting, the difference (a) between the top and bottom side increases as digging deeper (grind). Consequently the top side tends to become smaller. On the other hand, the bottom side remains constant in larger size. Hence, there is a limitation to narrow a spacing between the neighboring elements.

FIG. 2-4 shows a shape of the semiconductor (including the element side bonding metal layer, or the element side bonding metal layer and the bonding layer) which is processed by a micro blasting from both sides (Double side blasting).

As illustrated in FIG. 2-4, the double side blasting can reduce the difference (b) between the top and bottom sides significantly. As a result, it is possible to maintain a certain amount of the size of the top side. Furthermore, by adjusting the depth of digging, the part shown by e, that is, the area of the bottom side which remains when blasting from both sides, it can make smaller and narrowing the spacing between the neighboring elements.

The thermoelectric module of this embodiment according to the invention as shown in FIG. 2-1 and FIG. 2-2 are processed by a micro blasting from both sides in the both cases.

Hereinafter, the method for manufacturing the thermoelectric module of the embodiment according to the invention as shown in FIG. 2-1 will de described in detail.

The method for manufacturing the thermoelectric module of this embodiment according to the invention comprises the steps of;
forming a bonding layer on one side of the bonding metal layer;
forming a blasting mask on one side of the bonding layer;
blasting by a micro blast one side of the N-type or P-type plate semiconductor element which has a blasting mask thereon to the predetermined depth by a micro blast;
removing the blasting mask;
bonding the N-type plate semiconductor element or P-type plate semiconductor element to the insulating substrate in such manner that the blasted bonding layer face to the electric circuit metal layer;
forming a blasting mask on another side of bonding layer which is not processed of blasting;
making almost pillar shape and isolated elements by a micro blasting to another side of the N-type or P-type plate semiconductor which has a blasting mask thereon, in which the bonding metal layer and the bonding layer are formed on both sides of the elements;
removing the blasting mask;
combining the N-type semiconductor element with the P-type semiconductor element both of which have the bonding metal layer and the bonding on both sides thereof, thus forming the thermoelectric module comprising a top and a bottom side insulating substrates, an electric circuit metal layer fabricated on the each side of the substrates, a bonding layer fabricated on the electric circuit metal layer, a bonding metal layer fabricated on the bonding layer, and a pair of P-type and N-type semiconductor formed between the element side bonding metal layers.

FIG. 2-5 through FIG. 2-13 are explanatory drawings showing the method for manufacturing the thermoelectric module in accordance with the present invention. The substrate 2-2 having the electric circuit metal layer 4-2 fabricated thereon is manufactured as illustrated in FIG. 2-5.

As illustrated in FIG. 2-6, the bonding metal layer 8-1, 8-2 is fabricated on both sides of the element 20 (for example, a N-type semiconductor element), the bonding layer 6-1, 6-2 are fabricated further thereon, and a blasting mask 9 is fabricated in a pre-designed pattern on one side of the bonding layer 6-2.

Following that, a blasting process by a micro blasting is applied to one side of the element having a blasting mask fabricated until it reaches to a pre-designed depth, then the blasting mask is removed. The result is shown in FIG. 2-7.

As illustrated in FIG. 2-7, the bonding layer 6-2, the bonding metal layer 8-2 and the element 20 are ground excluding the area where the blasting mask remains as a pre-designed pattern. That is, as illustrated in FIG. 2-3, the shape of top-bottom for the single side blasting is shown. In the bottom area, the element continues to the neighbor and a U character shape is made.

Then rotating the element (+the bonding layer+the bonding metal layer) which applied by a blasting process on one side by 180 degree, and the one side of the bonding layer which processed is bonded to the substrate which having the electric circuit metal layer fabricated as FIG. 2-5.

The result is show in FIG. 2-8. As illustrated in FIG. 2-8, the electric circuit metal layer is fabricated n the substrate 2-2, wherein the bonding layer 6-2 processed by a single side blasting is placed thereon, where the bonding metal layer 8-2 is thereon, the element 20 is thereon, the bonding metal layer 8-1 is thereon, and the bonding layer 6-2 is repeatedly thereon.

And, further applying a blasting to the area where it is not yet processed in the area as shown in FIG. 2-8. Further, fabricating a blasting mask 19 as pre-designed pattern on the bonding layer 6-1 where a blasting is not yet processed.

Following that, a blasting process by a micro blasting is applied to another side of the element having a blasting mask fabricated until it reaches to a predetermined depth, then the blasting mask is removed.

As illustrated in FIG. 2-10, the bonding layer 6-1, the bonding metal layer 8-1 and the element 20 are ground excluding the area where the blasting mask remains as a pre-designed pattern, and it becomes a shape corresponding to the area which previously cut off.

As illustrated in FIG. 2-10, the N-type element which having a blasting process is formed on the substrate. On the substrate 2-2 shown in the FIG. 2-5, the electric circuit metal layer 4-2, the bonding layer 6-2, the bonding metal layer 8-2, the element 20 (the center part has similar shape as shown in FIG. 2-4.), the bonding metal layer 8-1 and the bonding layer 6-1 is placed thereon in this sequence.

By the same process as illustrated in FIG. 2-5 through FIG. 2-10 and corresponding to the FIG. 2-10, the P-type semiconductor element which having a blasting process on both sides is fabricated on the substrate as illustrated in FIG. 2-11. On the substrate as previously made it, the N-type and the P-type element which having a blasting process on both sides are assembled together with up and bottom position as illustrated in FIG. 2-12.

As a result, the thermoelectric module is made as FIG. 2-13 which comprises a plurality of [symbol] -shaped elements wherein;
a plurality of pairs of a P-type semiconductor element and a N-type semiconductor element are connected electrically in series via an electric circuit metal layer 4-1, 4-2 including
   two insulating substrates 2-1 and 2-2 aligned opposite,
   the electric circuit metal layers 4-1, 4-2 fabricated on each side of the substrates positioned face to face, and
   a pair of P-type N-type semiconductor element 10 and N-type semiconductor element 20 which having the bonding metal layers 8-1, 8-2 on both sides and the bonding layers 6-1, 6-2 thereon is made adjacent to the electric circuit metal layer by a blasting process applied from the both sides.

Hereinafter, the method for manufacturing the thermoelectric module of this embodiment according to the invention as shown in FIG. 2-2 will de described in detail.

The method for manufacturing the thermoelectric module of this embodiment according to the invention comprises the steps of:
forming a bonding layer on the electric circuit metal layer corresponding to its pattern;
forming a blasting mask on one side of the bonding metal layer;
blasting one side of the N-type or P-type plate semiconductor which having the blasting mask to the predetermined depth by a micro blasting;
removing the blasting mask;
bonding the N-type plate semiconductor or P-type plate semiconductor which the blasting process is applied as positioned the element side bonding metal layer stands opposite to the bonding layer on the insulating substrate;
forming a blasting mask on another element electrode layer which is not processed of blasting;
making almost pillar shape and isolated elements wherein the element side bonding metal layer formed by a micro blasting on another side of the N-type or P-type plate semiconductor which having the blasting mask,
removing the blasting mask,
combining the N-type semiconductor element having the element side bonding metal layer on both ends with the P-type semiconductor element, thus forming the thermoelectric module comprising a plurality of [symbol] -shaped elements, having connected electrically in series via the electric circuit metal layer and the bonding layer, which including a top and a bottom side insulating substrates, an electric circuit metal layer fabricated on the each side of the substrates, a bonding layer fabricated on the electric circuit metal layer, a bonding metal layer fabricated on the bonding layer, and a pair of P-type and N-type semiconductor formed between the element side bonding metal layers.

FIG. 2-14 through FIG. 2-21 are explanatory drawings showing the method for manufacturing the thermoelectric module in accordance with the present invention.

The substrate 12-2 having the electric circuit metal layer 14-2 fabricated thereon is made as illustrated in FIG. 2-14.

The bonding layer 16-2 is fabricated on the electric circuit metal layer 14-2.

As illustrated in FIG. 2-15, the bonding metal layer 18-1, 18-2 is fabricated on both sides of the element 120 (for example, a N-type semiconductor element), the bonding metal layer 18-1, 18-2 is fabricated further on that, and the blasting mask 29 is fabricated in a pre-designed pattern on another bonding metal layer bonding layer 18-2. Following that, a blasting process by a micro blasting is applied to one side of the element having a blasting mask fabricated until reach to a pre-designed depth, then the blasting mask is removed. The result is shown in FIG. 2-16.

As illustrated in FIG. 2-16, the bonding metal layer 18-2 and the element 20 are ground excluding the area where the blasting mask remains as a pre-designed pattern. That is, as illustrated in FIG. 2-3, the shape of top-bottom for the single side blasting is shown. In the bottom area, the element continues to the neighbor and a U character shape is made.

Then rotating the element (+the bonding metal layer) which applied by a blasting process on one side by 180 degree, and the one side of the bonding metal layer 18-2 which processed is bonded to the substrate 12-2 which having the electric circuit metal layer 14-2 fabricated thereon and the bonding layer 16-2 further thereon.

The result is show in FIG. 2-17. As illustrated in FIG. 2-17, the electric circuit metal layer 14-2 is fabricated on the substrate 12-2, where the electric circuit metal layer 14-2 is thereon, where on the bonding layer 16-2, the bonding metal layer 18-2 processed by a single side blasting is thereon, the element 20 is thereon, the bonding metal layer 18-1 is positioned thereon in this sequence.

Next, a blasting is applying to the rest of the top surface as show in FIG. 2-17. As illustrated in FIG. 2-18, the blasting mask 39 is fabricated as a pre-designed pattern on the bonding metal layer 18-1 where a blasting is not yet processed.

Following that, a blasting of a micro blasting is processed to another side of the element having a blasting mask fabricated until reach to a pre-designed depth, then the blasting mask is removed.

As illustrated in FIG. 2-19, the bonding metal layer 18-1 and the element 120 are ground excluding the area where the blasting mask positions as a pre-designed pattern, and it is cut to the shape corresponding to the area which previously cut off.

As illustrated in FIG. 2-19, the N-type semiconductor element which having a blasting process on both sides is fabricated on the substrate.

That is, on the substrate 12-2 in the FIG. 2-14, the electric circuit metal layer 14-2, the bonding layer 16-2, the bonding metal layer 18-2, the element 120 (the center part has similar shape as shown in FIG. 2-4.) and the bonding metal layer 18-1 are placed thereon in this order.

By the same process as described in FIG. 2-14 through FIG. 2-19, a P-type semiconductor element corresponding to the FIG. 2-19 which having a blasting process on the both sides is fabricated on the substrate as illustrated in FIG. 2-20. On the substrate as made it, the N-type element and the P-type element which having a blasting process on the both sides are assembled together with up and bottom position as illustrated in FIG. 2-12.

As a result, a thermoelectric module is made as FIG. 2-21 which comprises a plurality of [symbol] -shaped elements wherein;

a plurality of pairs of the P-type semiconductor element 110 and the N-type semiconductor element 120 are connected electrically in series via the electric circuit metal layer 14-1, 14-2 and the bonding layer 16-1, 16-2 including;
the two insulating substrates 12-1 and 12-2 aligned opposite thereof,
the electric circuit metal layers 14-1 and 14-2 fabricated on the each side of the substrates aligned opposite,
the bonding layer 16-1, 16-2 fabricated adjacent to the electric circuit metal layer, and
a pair of P-type semiconductor element 110 and N-type semiconductor element 120 which having the bonding metal layers 18-1, 18-2 on the both sides and the bonding layers 6-1, 6-2 thereon is made adjacent to the bonding layers by a micro blasting process applied from the both sides.

Besides, as illustrated in FIG. 2-22 through FIG. 2-24, a pattern of blasting mask formed on one side of the bonding layer may alternate with a pattern of the blasting mask formed on another side of the bonding layer.

FIG. 2-24 is an explanatory drawing of the blasting mask pattern. FIG. 2-24A shows a whole processing mask and FIG. 2-24B shows a partial processing mask. As described above, the shape of the element is improved by blasting from both sides, but the wafer of the element cut deeper or wider by primary blasting process tends to become fragile.

Consequently, the wafer is cut in the narrower part (it's circumference) by the primary blasting changing after changing the pattern of the blasting mask, the better shape can be processed without sacrificing the strength of the wafer of the element.

FIG. 2-22 is an explanatory drawing showing the configuration where the blasting mask is fabricated in a pre-designed pattern on one side then a blasting process is applied, and the processed bonding layer is bonded to the electric circuit metal layer, after that, another blasting mask is fabricated in a different pattern on another side.

FIG. 2-23 is an explanatory drawing showing the configuration where a blasting process is applied on another side.

Because the shape of the blasting mask is different between the upper and lower portion of the element (i.e., the size of the mask at bottom is smaller than that at top.) as illustrated in FIG. 2-23, when grinding the element during the second blasting, it is supported by the bonding layer and the bonding metal layer processed by the first blasting.

Consequently, it can make a stable processing.

The situation the part worked as a supporter during the first blasting and removed after the second blasting finished is like a configuration as shown in FIG. 2-10.

By combining the N-type semiconductor element with the P-type semiconductor element which having the bonding metal layer and the bonding layer fabricated on both sides made as above process together via the electric circuit metal layer as illustrated in FIG. 2-12, FIG. 2-13, a thermoelectric module is manufactured.

The P-type semiconductor element and the N-type semiconductor element used above may be a P-type or N-type Bi-Te group semiconductor respectively. The P-type semiconductor element and the N-type semiconductor element is sufficient as long as it has a thermoelectric characteristics and it is not limited to only the alloy of Bi—Te group but any kind of alloy having a thermoelectric characteristics is acceptable.

The electric circuit metal layer is made of a metal selected from a group consisting of Cu, Cr, Ni, Ti, Al, Au and Si or an alloy thereof, or laminated layers thereof.

A material of the electric circuit metal layer4-1, 4-2, 14-2, 14-2 is needed to function to join the substrate and the conductive metal made bonding layer.

For the substrate 2-1, 2-2, 12-1, 12-2, an insulating material of Al₂O₃, AlN, BN, SiC, Si,o Diamond, or an insulation coated Cu—W alloy or an insulating oxide compound or a nitride compound are typically preferred

A preferable material for the element side bonding metal layer is a metal selected from a group consisting of Cu, Ti, Cr, W, Mo, Pt, Zr, Ni, Si, Pd and C or an alloy thereof, or a laminated layer thereof.

And the insulating substrate is made of a insulating nitride compound or oxide compound composed of at least one selected from a group consisting of Al, Ti, Zr, Cu, B and W, or an insulating covered carbon compound.

For the bonding layer, a chemical element selected from a group consisting of Au, Ag, Ge, In, P, Si, Sn, Sb, Pb, Bi, Zn and Cu or an alloy thereof are preferable.

Furthermore, the space formed by a plurality of [symbol] -shaped elements may be filled with an insulating type synthetic resin.

And the bonding layer is generally made of a brazing material whose soldering point is below than 300 degree-C. This bonding layer functions to join the semiconductor element with the electric circuit metal layer.

A semiconductor substance is typically very fragile and difficult to process, therefore a dicing saw has been used conventionally. Because the present invention uses a micro blasting to process, the process time is very fast.

The electric circuit metal layer and the bonding layer are both fabricated by a method such as wet plating, CVD, sputtering, vacuum evaporation or ion plating etc. A mask layer with an opening window is formed by the steps of coating a photoresist on the bonding layer and the bonding metal layer, exposing the photo resist and making a window in a predetermined area.

It is preferable step of forming a dielectric substrate such as SiO₂, SiNx by an electron beam or CVD or the like prior to coating a photoresist, then adhering a photoresist film or a dry film and coating a photoresist, opening a window, etching the dielectric substrate film, and transferring the mask pattern onto the dielectric substrate film.

It is shown the configuration when etching is further carried out on the area of the opened window and the conductive bonding layer and the bonding layer are removed by etching.

These processes are standard methods applied for typical semiconductor manufacturing process.

Referring to FIG. 1-5, it is shown that the substrate which having the electric circuit metal layer 4-1 (4-2) and the blast stopper layer 6-1 (6-2) after the opening window has been made by the process described above.

A semiconductor element, for example, a Bi—Te group plate shape semiconductor element, the conductive bonding metal layer is fabricated on the wafer thereon. By rotating the wafer, this is bonded to another Bi-Te group wafer which is previous made having the bonding metal layer fabricated thereon. Method of bonding may be soldering or brazing. The bonding material is preferably a chemical element selected from a group consisting of Au, Ag, Ge, In, P, Si, Sn, Sb, Pb, Bi, Zn and Cu or an alloy composed thereof.

As described above step, making a mask, exposing it in a designed shape and pattern, developing and etching.

An area excluding the area where covered by a mask is processed by a micro blasting and the area of semiconductor layer with no masking is ground instantly in very short time to the etching stopper layer at the bottom.

The recommendable mask is, for example, a dry film or a Cupper metal film of10-100 micron thickness when blasting the semiconductor element.

When processing this kind of shape by using a dry etching, its process time is 0.1-1 hour/micron, however it can grind the 100 micron in the range of 1 to 3 minutes by the micro blasting according to the present invention. It's processing speed is faster as 500-5000 times.

In addition, when using a dicing saw in a conventional method, it can process only straight line, but the present invention allows any arbitrary shape of the thermoelectric semiconductor by making a mask in arbitrary pattern in accordance with the invention.

An ultra fine micro blasting equipment on the market may be used for this micro blasting process. In this equipment, a very hard material such as corundum with diameter 3-4 micron meter is used as an abrasive, Hence, it becomes possible to cut off the width of 10-100 micron meter in a few minutes.

A mask fabricated on the semiconductor element is removed away by an etching process.

Method of the bonding may be soldering, brazing or silver soldering.

The dimensions of a module made, for example, the electric circuit metal layer has dimensions ranging from 10-1000 micron meter, the bonding metal layer has 1-100 micron meter, and the bonding layer such as solder has 10-100 micron meter.

A method for forming the electric circuit metal layer is selected at least one from a group a wet plating, CVD, sputtering, vacuum evaporation or ion plating or combination thereof.

And as described above, the various soldering metal such as Sn—Sb, Sn—Cu, Sn—Ag, Sn—Ag—Bi—Cu, Sn—Zn, or Sn—Pb is used as a bonding material of soldering.

Besides a Bi—Te group of semiconductor as described, other type of thermoelectric semiconductor may be used.

The dimensions of the substrate of the module made as above has, for example, in the range from 1×1 mm to 20×20 mm.

In accordance with the present invention, it is possible to make a significantly narrow spacing between a P-type element and N-type element such as 10 micron meter, and hence the arrangement of the thermoelectric elements can be made in very high area density. Finally, the space between the thermoelectric elements may be filled by a synthetic resin for example an epoxy resin, and may not be mandatory filled.

FIG. 3-1 is an explanatory drawing showing the method for processing a substrate in accordance with the invention.

The embodiment of a method for processing a substrate according to the invention is a method for processing a substrate comprising the steps of:
covering a surface of the processed substrate with a masking material in the pre-designed pattern;
placing a supporting part on the rear side of the processed substrate where the portion of the supporting part corresponding to the masking material is made to be a convex part and the rest portion being a concave par; and
blasting an abrasive to the processed substrate which covered by the masking material and perforating the area of the concave part.

The surface processed by the perforation has an about vertical plane.

Hereinafter, a word expressed as a vertical plane does not mean a vertical in strict manner but includes approximately vertical plane.

The processed substrate may be fixed to a supporting part by a fixing method.

FIG. 3-1(a) is one of explanatory cross sectional view of a configuration showing a method for processing the substrate where the surface of the processed substrate is coated by a masking material and the substrate supporting part is placed under the back side of the substrate. As illustrated in FIG. 3-1 (a), a portion of the substrate of the processed material is coated by a masking and the rest of it is removed and perforated leaving that portion. Then, place the substrate supporting part 1 which comprises a plurality of convex parts having a vertical plane of the side wall, and concave parts forming the circumference of the convex part which are corresponding to the target pattern of the substrate, for example, a thermoelectric semiconductor substrate. Next, place the thermoelectric semiconductor substrate 2 on the substrate supporting part in a position as the surface of the plural convex parts arranged to make a contact, and place the masking material which correspond to a designed pattern of the substrate, on the thermoelectric semiconductor substrate 2.

By arranging like this, the masking material is placed corresponding to a designed pattern, the lower part of the thermoelectric semiconductor substrate where a masking material is not placed corresponding to a convex part of the substrate supporting part and in an unsupported condition. Further more as illustrated in FIG. 3-1(a), the axial direction of the convex part of the substrate supporting part crosses at right angle to a longitudinal direction of the thermoelectric semiconductor substrate. After sand blast (blasting an abrasive) is applied from the top side in the drawing under this condition, as illustrated in FIG. 3-1(b) the substrate supporting part supports the area to be remained of the processed substrate, on the other hand, the place under the area to be removed is vacant and the processed substrate is perforated about vertically, and it is processed as a designed shape with high accuracy.

To demonstrate the difference clearly, the relation with a conventional type substrate supporting part, a substrate processed, and a masking material will be shown. FIG. 3-2 is one of explanatory cross sectional view showing a conventional configuration where a surface of the substrate is coated by a masking material and a substrate supporting part is placing under the substrate. As illustrated in FIG. 3-2(a), it is same as conventional method that a part of the substrate of the processed material is coated by a mask is left without cutting but rest of the are is cut and perforated. By the conventional method, the flat plane shape substrate supporting part 101 is placed, where the substrate, for example the thermoelectric semiconductor substrate 102, is placed on the substrate supporting part, and the masking material 103 corresponding to the target pattern of the substrate is further placed on the thermoelectric semiconductor substrate 102.

When processing a sand blast from the top side in this drawing, the substrate supporting part supports whole the part of the substrate to be processed but not only the area to be left. It is resulting that as illustrated in FIG. 3-2(b), the width is getting narrower as the digging depth is increasing, so that the side plane of the processed area 104 is not made vertically but with a skirt formed. Therefore the cross sectional area of the bottom side is getting larger as approaching to the bottom side, consequently, there is a limitation with a fine accuracy processing.

As explained above, the substrate supporting part of the present has a unique shape. That is, a substrate supporting part wherein the substrate to be processed by a sand blast is placed thereon and which includes a plurality of convex parts arranged corresponding to the target pattern of the processed substrate and concave parts forming the circumference of the convex part. Further, the substrate to be processed comprises a P-type thermoelectric semiconductor element or N-type thermoelectric semiconductor element. And the substrate supporting part including the convex part is formed on the flat surface material.

FIG. 3-3 is one of cross sectional view showing the fundamental method for processing the substrate in accordance with the invention. As illustrated in FIG. 3-3(a), the substrate 2 to be processed is placed on the substrate supporting part 1 which comprises a plurality of convex parts 5 arranged corresponding to the target pattern of the substrate to be processed and concave parts 6 forming the circumference of the convex part. Next, as illustrated in FIG. 3-3(b), the area where is not covered by a masking material is removed by a sand blasting. The area which is the largest distance from the mask is processed at the highest speed and the area which closer distance from the mask has a slower processing speed as the speed of sand particles going slower. Next, as illustrated in FIG. 3-3(c), once a small perforation hole is opened, the surrounding area protrudes sharply to the vacant space and becomes easier for grinding. Further the sand particles fall down into the concave part 6, and it is not gathering in the depression so it will not disturb the processing.

As a result, as illustrated in FIG. 3-3(d), the side wall 8 of the area processed tends to be made vertical plane.

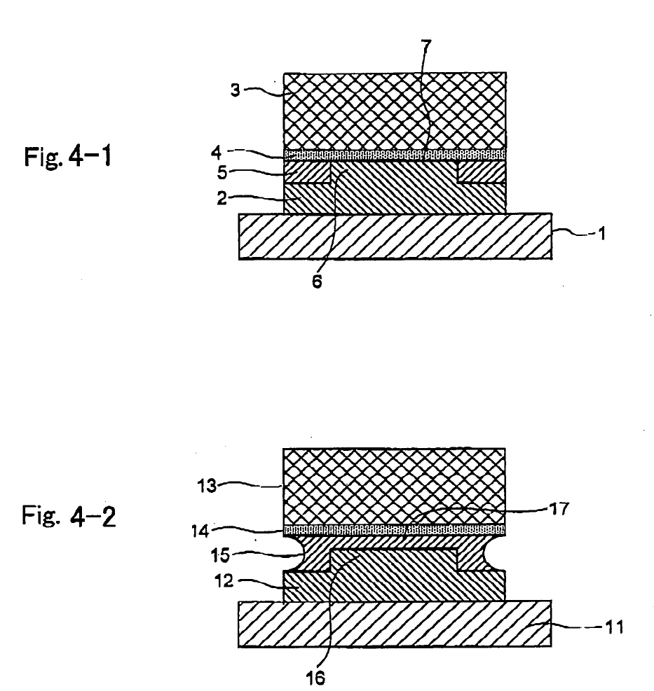

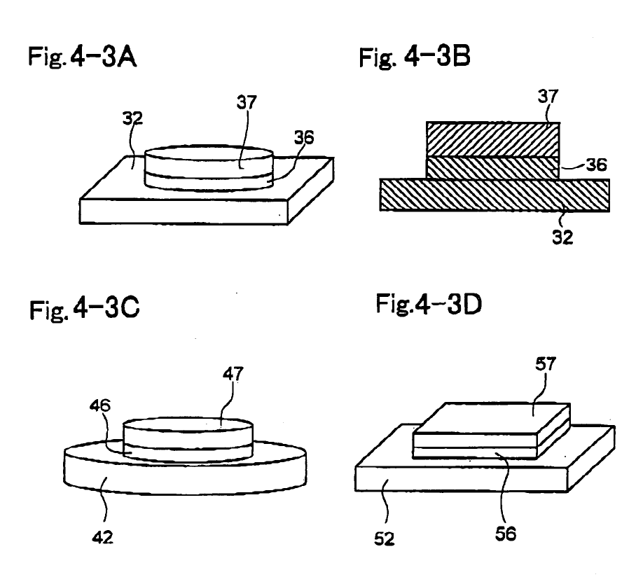

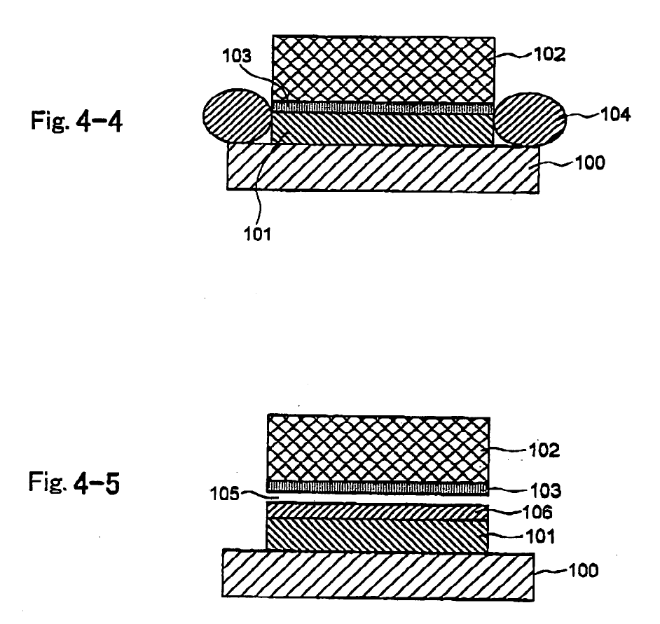

To demonstrate the difference clearly, the conventional fundamental method for processing a substrate will be described. FIG. 3-4 is one of explanatory cross sectional view showing a conventional fundamental method for processing a substrate. As illustrated in FIG. 3-4(a), the flat plate substrate supporting part 101 is placed, where the substrate to be processed is placed on the substrate supporting part, and the masking material 103 corresponding to the target pattern of the substrate to be processed is further placed on the substrate to be processed 102. Then, as illustrated in FIG. 3-4(b) the area where the masking material is not coated is removed by a sand blasting. As illustrated in FIG. 3-4(c), even a small perforation hole 106 is opened in the processed substrate, the processing speed in the area around the masking material 107 is slow and when the sand particles gathering in the depression, the processing speed goes further smaller, it is difficult to make the side wall of the processed part 108 vertically.

In the above description, a word of “perforation processing” means a removal of a partial area of the processed material (substrate) thoroughly from the top surface to the bottom and either method of a perforating or a cutting is workable. In the case when making many elements by cutting a processed substrate, if the elements scatters prior to finishing of cutting process, it may cause a problem and also in the case when carrying out a sand blasting in order to make a shape and position of the elements, the substrate is needed to fix with a supporting part by a means of adhesion material or others. It is recommended to fix it in order to protect a drift of the position of the mask and the supporting part when cutting a hole.

The mask pattern is in principle same as the pattern which is a pattern of the area to remain, however in the practical case, considering the various conditions such as amount of wearing in the lateral direction or a side etching of the masking material, it is modified of a type and thickness of the processed material, a type of sand particle etc. And the pattern of the supporting part for the substrate supporting part is in principle same as a pattern of the area to remain when masking or blasting, however in real case it is modified same as for the masking material. Therefore, the supporting part sometimes happens to be smaller than the masking. The concave part of the supporting part may be perforated through the back plane of the substrate supporting part to allow easier draw off the sand particles.

By using the method for processing the substrate of the invention, a thermoelectric module can be made. One embodiment of the method for manufacturing a thermoelectric module in accordance with the invention comprises the steps of:
placing a thermoelectric semiconductor substrate adjacent to the surface of the convex part of the supporting parts which having a plurality of convex part arranged on the flat plane material corresponding to a target pattern of a thermoelectric semiconductor substrate;
placing a film shape material on the thermoelectric semiconductor substrate;
exposing and etching for the film shape material;
forming a masking material as a pre-designed pattern corresponding to the processed shape of the thermoelectric semiconductor substrate;
blasting an abrasive to the thermoelectric semiconductor substrate covered by the masking material;
perforating towards the concave part surrounding a convex part to process the thermoelectric semiconductor substrate;
forming a plurality of pillar shape elements arranged comprising the convex part, the thermoelectric semiconductor element, and the masking material;
removing the masking material;
transferring the thermoelectric semiconductor elements which the masking material is removed on the transferring part,
bonding the thermoelectric semiconductor element to the substrate having the electric circuit metal layer.

By the perforating process described above, the processed side wall is made about vertical plane. Furthermore, the thermoelectric semiconductor substrate is consisting of a P-type thermoelectric semiconductor substrate and a N-type thermoelectric semiconductor substrate. When assembling the P-type thermoelectric semiconductor substrate and the N-type thermoelectric semiconductor substrate, the shape of the P-type thermoelectric semiconductor substrate and the N-type thermoelectric semiconductor substrate are arranged alternatively in both of vertical and horizontal direction. And transferring the thermoelectric semiconductor elements to the transferring part has the P-type thermoelectric semiconductor elements and the N-type thermoelectric semiconductor elements transferred to different transferring part respectively and makes PN elements.

A method for manufacturing a thermoelectric module using the process for the substrate in accordance with the invention will be described below.

The wafer 2 made of Bi—Te group semiconductor with a dimension of 20 mm×20 mm square and 0.1 mm thickness is prepared as a material for the P-type thermoelectric semiconductor (element) is prepared. It is soldered with Ni and Sn on the wafer for the use in the later soldering process.

The substrate supporting part having a shape shown in FIG. 3-5(a) is made from a transmissive Aluminum plate. A square shape convex part 5 (or protruding portion part) is made to remain as the rest of the area to cut in a shape of concave. The top surface of plural convex parts are positioned on the same plane and the dimension of one convex part is 0.16 mm×0.16 mm.

As illustrated in FIG. 3-5(b), an ultra violet ray curing type adhesive used for a dicing tape is adhered on the convex part of the substrate supporting part, and a Bi—Te group semiconductor wafer is bonded thereon. Then, as illustrated FIG. 3-5(c), it is carried out that adhering a dry film as a mask on the wafer and carrying out an exposure and developing to make the mask in the same size and same position as the convex part of the substrate supporting part. Consequently, the mask remains on the right top position of the convex part of the substrate supporting part,

FIG. 3-6 shows an example of pattern of the mask and the convex parts of the substrate supporting part. FIG. 3-6 is also a pattern showing the area that the substrate to remain, that is a pattern of the designed shape.

Furthermore as illustrated in FIG. 3-5(d), when a sand blasting is applied, the area of the wafer is cut excluding the area where covered by a mask, then the arrangement of the square pillars is made where positioned between the mask and the convex part of the substrate supporting part (Refer to FIG. 3-5(e)).

The masking material is removed after finishing the perforation process by a sand blasting. As a result as shown in FIG. 3-5(f), the wafer is sliced into the square shape discrete P-type thermoelectric semiconductor elements of 0.16 mm square in the configuration that is fixed and positioned on the convex parts of the substrate supporting part.

The same process referred to FIG. 3-5(a) thorough FIG. 3-5(f) is carried out on a Bi-Te group semiconductor wafer with dimensions of square of 20 mm and 0.1 mm thickness to make it as a N-type semiconductor elements.

Next, a P-type thermoelectric semiconductor element arranged as described above is transferred on the second fixing jig (Refer to FIG. 3-5(g) and FIG. 3-5(h)). The second fixing jig 11 is made as that an ultra violet ray curing type adhesive is coated on a flat surface plate such as a glass plate. As illustrated in FIG. 3-5(g), the second fixing jig 11 is placed over and adhered to the elements arranged on the substrate supporting part 1, then as illustrated in FIG. 3-5(h), by applying a ultra violet light to the adhesive on the substrate supporting part 1, its adhesive power is made weaken so that the elements moved to the surface of the fixing jig 11.

Further, the arranged N-type thermoelectric semiconductor element is transferred as inserting to fit between each elements of the P-type thermoelectric semiconductor arranged on the second fixing jig 11. In other words, as shown in FIG. 3-5(i), the N-type thermoelectric semiconductor elements 13 arranged on the substrate supporting part 1 are transferred and positioned between each elements of the P-type thermoelectric semiconductor 12 arranged on the second fixing jig 11 in the pre-designed pattern. It is illustrated in FIG. 3-5(j)

FIG. 3-7 shows an arrangement pattern of the P-type thermoelectric semiconductor elements transferred on the second fixing jig and the N-type thermoelectric semiconductor elements. As illustrated in FIG. 3-7, the P-type and N-type thermoelectric elements are positioned alternatively in both of vertical and horizontal direction.

Now preparing a substrate having the electric circuit metal layer in a pre-designed pattern by metalizing on the insulating substrate. As illustrated in FIG. 3-5(k), the P-type and N-type thermoelectric elements positioned alternatively in both of vertical and horizontal direction are soldered to the substrate having the electric circuit metal layer in a construction as sandwiched between the substrates with the electric circuit metal layer.

The electric circuit metal layer has a pre-designed pattern so that all P-type and N-type thermoelectric elements are alternatively connected in series when the P-type and N-type elements arrangement is sandwiched from an upper and lower side.

Firstly a flux is coated on the lower substrate, then mounting the elements arranged on the second fixing jig, and soldering with heating. In this process, when heated, the removal of the second fixing jig is realized at the same, then it becomes in the configuration as the elements are mounted on the lower substrate. Next a flux is coated on another upper substrate, then soldering is carried out as same manner as the lower substrate .

The process described above provides a easy manufacturing method for a thermoelectric module which has a small size of substrate, a vertical plane side wall made by perforation process and high density of the elements.

The manufacturing method for a thermoelectric module described above uses a technique of temporary and removable fixing of a thermoelectric module wafer to the supporting part, and a method for transferring the thermoelectric semiconductor element processed by a blasting to the substrate which having the electric circuit metal layer, but other methods are available. Another method for manufacturing a thermoelectric module in accordance with the invention is a method wherein
the convex part is made of the an electric circuit metal layer;
the supporting part is made of a substrate having the electric circuit metal layer;
the arrangement of the convex parts of the thermoelectric substrate is a final bonding configuration.

For example, the electrode of the substrate having the electric circuit metal layer is made of a convex shape, and the thermoelectric semiconductor wafer is soldered on the convex part. The bonding is not a temporary fixing but a permanent fixing in electrically and mechanically as final embodiment as a product. Following that, it is carried out of putting a dry film as a mask on the semiconductor wafer, exposing and etching so that the mask remains in a predetermined size at the position corresponding to the convex part of the electrodes. In this case, same as previous example, the a convex part of the electrodes supports the thermoelectric semiconductor wafer, and because the circumference becomes a concave shape relatively, there is an effect to make a side wall to a more vertical plane when perforating the thermoelectric semiconductor by a blasting and slicing into a discrete element.

According to this method, the time when finishing the process of the thermoelectric semiconductor wafer, the bonding process to the substrate having the electric circuit metal layer completes as well. Therefore, whole work for the thermoelectric module completes by assembling in occlusion and bonding the substrate having the electric circuit metal layer with a P-type thermoelectric semiconductor element bonded to the substrate having the electric circuit metal layer with a N-type thermoelectric semiconductor bonded.

The P-type semiconductor or N-type semiconductor is sufficient as long as having thermoelectric characteristics, it is not limited to only the alloy of Bi—Te group, and any thermoelectric alloy is acceptable.

The electric circuit metal layer is as mentioned above made of a metal selected from a group consisting of Cu, Cr, Ni, Ti, Al, Au, Ag and Si or an alloy thereof, or a multi laminated layers of thereof. The electric circuit metal layer is required to function as a bonding material between a substrate and conductive metal made bonding layer.

The electric circuit metal layer is fabricated by a method such as wet plating, sputtering, vacuum evaporation or ion plating etc.

The substrate is typically made of a insulating type Al₂O₃ , AlN, BN, SiC, Si, and Diamond, or an insulation covered Cu—W alloy or an insulating type oxide compound or nitride compound are preferable.

As described above, a preferable material for the element side bonding metal layer is a metal selected from a group consisting of Cu, Ti, Cr, W, Mo, Pt, Zr, Ni, Si, Pd and C or an alloy thereof, or a multi laminated layers thereof. The element electrode layer is formed on both sides of the P-type and N-type thermoelectric semiconductor.

A method for manufacturing the element side bonding metal layer is either a single method selected from a group consisting of wet plating, sputtering, vacuum evaporation or ion plating or a combination thereof.

And the bonding layer is generally made of a brazing material whose soldering point is below than 300 degree-C.

The bonding layer works to join the thermoelectric semiconductor element with the electric circuit metal layer. And a material for a bonding layer is a brazing material whose soldering point is below than 300 degree-C. and it is preferable to include a chemical element selected from a group consisting of Au, Ag, Ge, In, P, Si, Sn, Sb, Pb, Bi, Zn and Cu or an alloy thereof.

And for a bonding material of soldering, a various soldering metal such as Sn—Sb group, Sn—Cu group, Sn—Ag group, Sn—Ag—Bi—Cu group, Sn—Zn group, Sn—Pb group and Au—Sn group is suitable.

A bonding layer is fabricated by a method such paste printing, wet plating, sputtering, vacuum evaporation etc.

For the thermoelectric element made according to the process, the space made by a plurality of [symbol] -shaped elements may be filled by synthetic resin.

Furthermore, the one of embodiments of the module having a micro element according to the invention is a module including a plurality of micro elements are mounted in very high density on the substrate wherein the electrodes of the micro elements are bonded via the bonding layer to the electric circuit metal layer of the substrate corresponding to the electrodes of the micro element, and the electric circuit metal layer of the substrate has a container which absorbs an excess bonding material that is a part of bonding layer forming material when pressurized.

FIG. 4-1 is a explanatory drawing showing one embodiment of the module having a micro element in accordance with the invention. There are plural micro elements placed with high density on the substrate. The electrode 4 of the micro element 3 is bonded with the corresponding electric circuit metal electrode 2 of the substrate 1 via a bonding layer. The electric circuit metal layer of the substrate has a container to absorb an excess part of the bonding material when pressured. It may alternatively work that the electric circuit metal layer having the flat plate and the protruding portion, and the electric circuit metal layer having a protruding portion in the side of facing to the micro element, and the container parts may be made from a protruding portion, the flat plate and the electrodes of the micro element.

As illustrated in FIG. 4-1, the electric circuit metal layer of the substrate 1 having the flat plate 2 and the cylindrical protruding portion 6 in the side facing to the micro element 3, and the area 5 made by the circumference of the protruding portion 6 and the flat plate 2 forms a container parts to absorb an excess part of the bonding material when pressured.

The micro element of the invention such as a micro electronic element/micro semiconductor element has a squared pillar with a dimension of 50-150 micron meter. But the size is not limited to the range referred above.

FIG. 4-1 shows one embodiment of the module wherein a micro element such as a micro electrical element/micro semiconductor element is assembled by pressing towards the electric circuit metal electrode of the substrate which having a protruding portion. That is, by the pre-determined heat and pressure, the top surface of the protruding portion of the electric circuit metal electrode and the electrode 4 of the micro element is assembled together without a gap there-between.

By pressing the micro electrical element/micro semiconductor element towards the electrodes positioned in the side of the substrate where the protruding portion is positioned, an excess bonding material that is a part of bonding layer forming material between the micro electrical element and the electrodes of the electric circuit layer is forced to move from the center of the protruding portion to the surrounding area, then the container placed in the surrounding area of a protruding portion accommodates it. Therefore, it can stop an swelling out of the excess bonding material to the outside of the micro electrical elements and the electrodes of the electric circuit layer consequently, it can prevent causing an electrical short problem.

Furthermore, it can arrange a plural of micro elements on the substrate with high density mounting capability once narrowing the pitch between the micro elements by preventing a swelling out of the bonding material to the outside from the micro electrical elements and the electrodes of the electric circuit layer.

FIG. 4-2 is an explanatory drawing showing one embodiment of the module having a micro element in accordance with the invention. In this embodiment, the micro elements are pushed to the electric circuit metal layer with some distance. And the electrode 14 of the micro element 13 is connected via the bonding layer 17 to the electric circuit metal layer 12 on the substrate 11 which aligned opposite. The electric circuit metal layer 12 on the substrate has a container 15 to absorb a pressured excess part of the bonding material. As illustrated in FIG. 4-2, the electric circuit metal layer 12 has a protruding portion 16 in the facing side to the micro element 13, and the container part 15 is formed from the protruding portion 16 and the electrode 14 of the micro element 13.

As illustrated in FIG. 4-2, for example, the electric circuit metal layer 12 of the substrate 11 has a square pillar shape protruding portion 16 which is in the facing side to the micro element 13, and the portion 15 cut off around the protruding portion 16 forms a container part to absorb an excess part of the bonding material when pressured.

FIG. 4-2 shows one embodiment of the module wherein a micro element such as a micro electrical element/micro semiconductor element is assembled floating from the side of the electric circuit metal electrode of the substrate which having a protruding portion. It is assembled in the configuration the gap is made between the protruding portion of the electric circuit metal electrode and the bottom surface of the electrode 4 of the micro element.

In this embodiment, a micro element 13 such as a micro electrical element/micro semiconductor element is forced towards the electric circuit metal electrode of the substrate having a protruding portion 16, under the condition to keep some spacing between the top surface of the protruding portion of the electric circuit metal electrode and the bottom surface of the electrode 4 of the micro element, when giving a pressure, the bonding layer 17 is formed with predetermined thickness between the micro element and the electric circuit metal electrode, an excess part of the bonding material is put from the center of the protruding portion to the circumference of the protruding portion and accommodated in the container 15 formed around the protruding portion. And the bonding material is absorbed in the inner part of the micro element and the electric circuit metal electrode, its swell out exceeding to the outside around the circumference can be protected, consequently it can prevent causing an electrical short problem.

Furthermore, it can arrange a plural of micro elements on the substrate with high density mounting capability once narrowing the pitch between the micro elements by preventing an swell out of the bonding material to the outside from the micro electrical elements and the electrodes of the electric circuit layer. And a material for a bonding layer is a brazing material whose soldering point is below than 300 degree-C. and it is preferable to include a chemical element selected from a group consisting of Au, Ag, Ge, In, P, Si, Sn, Sb, Pb, Bi, Zn and Cu or an alloy thereof.

The shape of the protruding portion is a cylindrical pillar or squared pillar with the top surface being a flat plane as described above. In order to prevent securely an swell out of the bonding material to the outside from the circumference of the micro elements and the electrodes of the electric circuit layer, it is required to establish a rule between the volume of the bonding material and the volume induced an area of the electric circuit metal layer and a height of the protruding portion.

In this module which having a micro element, a volume of the bonding material forming the bonding layer must be less than or equal to a value subtracting a volume of the protruding portion from a volume induced an area of the electric circuit metal layer of the substrate multiplied by a height of the protruding portion

FIG. 4-3 shows a protruding portion of the electric circuit metal layer and a bonding layer. FIG. 4-3A is a perspective view showing one embodiment of a protruding portion of the electric circuit metal layer and the bonding layer. FIG. 4-3B is a cross sectional view showing a protruding portion of the electric circuit metal layer and the bonding layer. FIG. 4-3C is a perspective view showing another embodiment of a protruding portion of the electric circuit metal layer and the bonding layer. FIG. 4-3D is a perspective view showing a different embodiment of a protruding portion of the electric circuit metal layer and the bonding layer.

In the embodiment shown in FIG. 4-3A, the electric circuit metal layer comprises a squared flat plate part 32 and a cylindrical pillar protruding portion 36, and the bonding layer 37 made of a bonding material is formed on the top surface of a protruding portion 36, corresponding to the area of the protruding portion. FIG. 4-3B is a cross sectional view. An excess bonding material swell outing to the circumference of the protruding portion is accommodated in the container formed by the flat plate of the electric circuit metal layer and the circumference of the protruding portion when the electrode of the micro element is forced to push towards the electric circuit metal layer having a bonding layer fabricated on the protruding portion.

In the embodiment shown in FIG. 4-3C, the electric circuit metal layer comprises a circle flat plate and a cylindrical protruding portion 46 formed thereon. The bonding layer 47 made of a bonding material is formed on the top surface of the protruding portion 46, corresponding to the area of the protruding portion. The cross sectional view is same as FIG. 4-3B. In this embodiment, the electrode of the micro element is forced at predetermined force towards the electric circuit metal layer having the bonding layer on the protruding portion and the excess bonding material put into the circumference of the protruding portion is accommodated in the container formed by the flat plate of the electric circuit metal layer and the circumference of the protruding portion.

In the embodiment shown in FIG. 4-3D, the electric circuit metal layer comprises a square flat plate 52 and a square pillar protruding portion 56 formed thereon. The bonding layer 57 made of a bonding material is formed on the top surface of the square shape protruding portion 56, corresponding to the protruding portion. The cross sectional view is same as FIG. 4-3B. In this embodiment. the electrode of the micro element is forced at predetermined force towards the electric circuit metal layer having the bonding layer on the protruding portion and the excess bonding material put into the circumference of the protruding portion is accommodated in the container formed by the flat plate of the electric circuit metal layer and the circumference of the protruding portion.

Furthermore, in the module having a micro element in accordance with the invention, the protruding portion is made of same conductive metal as the electric circuit metal layer or the electrode of the micro element or different conductive metal.

Next, a method for bonding a narrow pitch of the micro element according to the invention will be described. One of embodiments of a method for bonding a narrow pitch of the micro element of the invention is a method for arranging a plurality of the micro elements in very high density on the substrate comprising the steps of:
providing a protruding portion on the electric circuit metal layer of the substrate corresponding to the electrode of the micro element;
placing a pre-determined amount of the bonding material between the electrode of the micro element and the protruding portion to form bonding layer;
applying a pressure to press the micro element to the electric circuit metal layer of the substrate through the bonding material and containing the excess bonding material in the space made by the protruding portion and the electrode of a micro element; and
forming the bonding layer.

As described referring to the FIG. 4-3, as first step, providing a protruding portion on the electric circuit metal layer of the substrate corresponding opposite to the electrode of the micro element. That is, the electric circuit metal layer comprises a circle or square flat plate and a cylindrical or square (any other shape is acceptable) pillar protruding portion. Next, placing a pre-determined amount of the bonding material between the electrode of the micro element and the protruding portion to the form bonding layer, It is easy to form a bonding layer with same shape as a protruding portion in projection, for example, a cylindrical bonding layer to a cylindrical protruding portion and a square bonding layer to a square protruding portion, and it is not limited to but different shape works. Next, by giving a pressure to press the micro element to the electric circuit metal layer of the substrate which comprises a protruding portion and flat part of the substrate, through the bonding material and absorbing an excess bonding material in the space made by the circumference of the protruding portion, top of the flat plate part and the electrode of a micro element and forming the bonding layer. And the bonding layer may be formed at least on the top of the protruding portion or on the element side

In a method for bonding a narrow pitch of the micro element according to the invention, the amount of the bonding material is determined so that an excess bonding material will not swell out from the circumference of the micro element and the electric circuit metal layer. In order to prevent securely of the bonding material swells out to the outside from the circumference of the micro elements and the electrodes of the electric circuit layer, it is required to establish a rule of the relationship between the volume of the bonding material and the volume derived from an area of the electric circuit metal layer and the height of the protruding portion. That is, the volume of the bonding material forming the bonding layer must be less than or equal to a value subtracting a volume of the protruding portion from a volume induced an area of the electric circuit metal layer of the substrate multiplied by a height of the protruding portion

Furthermore, in a method for bonding a narrow pitch of the micro element according to the invention, the electrode of the micro element is pressed towards the protruding portion so that no gap is made between the electrode of the micro element and the protruding portion. In addition, for the purpose of making no gap between the electrode of the micro element and the protruding portion, the bonding layer may be formed between the electrode of the micro element and the top surface of the protruding portion and between the electrode of the micro element and the circumference of the protruding portion, by pressing the electrode of the micro element towards the protruding portion.

The forming process as described above differs depend on the mounting method of the micro element and the electric circuit metal layer. ie, it depends on whether a gap is made or not made between the upper surface of the electrode of the micro element and the top surface of the protruding portion of the electric circuit metal layer.

According to the present invention, because the bonding material to join the micro element such as a micro electric element/micro semiconductor element or the like with the electric circuit metal layer will not swell outside the circumference of the micro element and the electric circuit metal layer, it can prevent causing a electrical short problem, also it allows to narrow the pitch between the micro elements, consequently the high density arrangement is made possible.

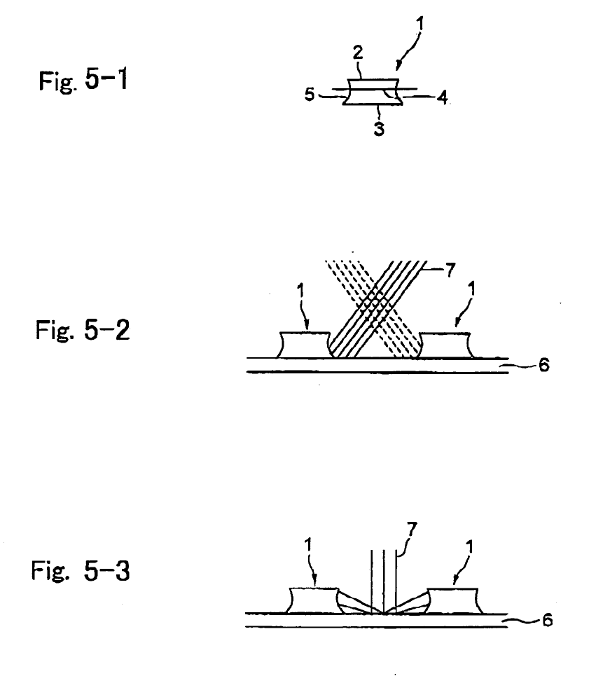

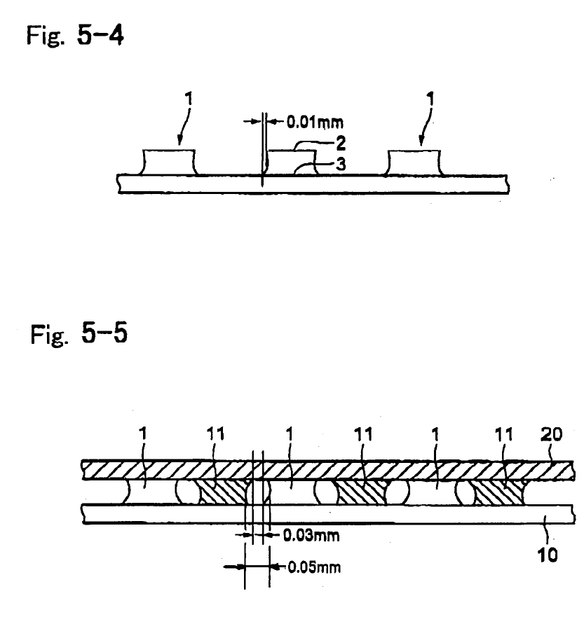

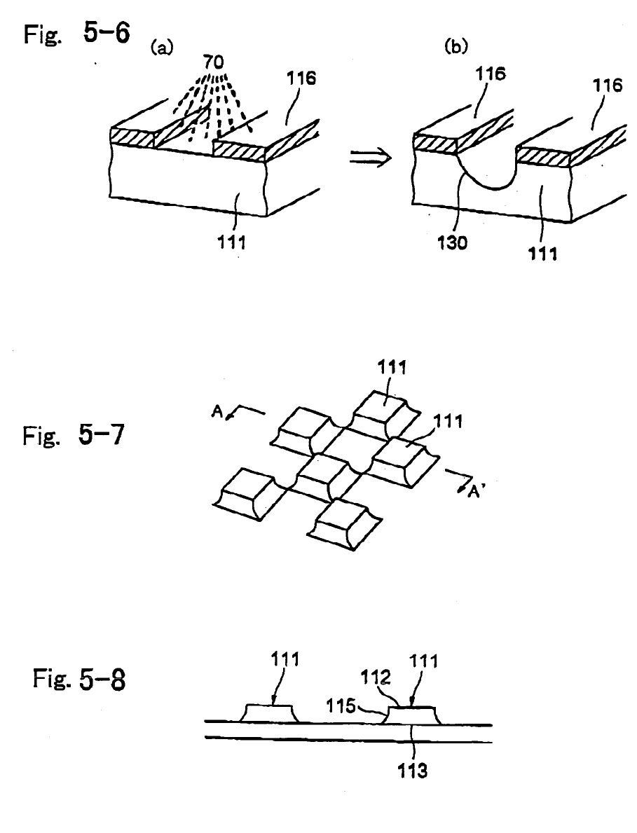

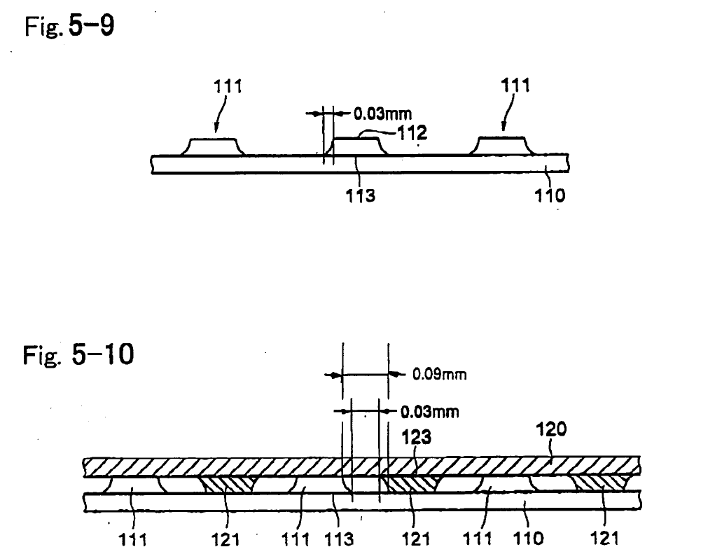

FIG. 5-1 is a cross sectional view showing a thermoelectric semiconductor (element) which processed by the method for the substrate according to the invention. Precisely saying, it is a thermoelectric module having an element 1 including an hour-clock shape 5 and a middle part 4 which is thinner than the top 2 or bottom part 3.

When manufacturing this type of element by a sand blasting process on a thermoelectric semiconductor wafer, the area of the element is covered by a masking material such as a dry film, and rest of the area is ground by a sand blasting, in addition to the processing to the bottom direction, the processing to the side direction is carried out as well.

By processing to the side direction, side wall of the element is well removed. But the processing to the side direction will not progress uniformly. As the area of the upper and lower area where proximate to the mask is hard to grind, the middle part of the element is ground so well and made as an hour-clock shape. As a result, comparing with the method no use of the present invention, the bottom area is grounded more and the area of the bottom can be made closer to the area of the bottom.

FIG. 5-2 and FIG. 5-3 are explanatory drawings showing a method of blasting an abrasive in accordance with the invention. As illustrated in FIG. 5-2, one of processing methods for the side wall is carried out at inclined angle of the blasting direction against the processed part but not vertical direction. According to this method, sand particles 7 are injected directly to the side wall of the element 1 at declined angle against the processed part on the base plate 6. Another method is, as illustrated in the FIG. 5-3, a secondary grinding method where utilizing a secondary collision of particles after collided. The processing to the side wall is carried out by the steps, first the sand particles 7 are injected from the upper position to the processed part placed on the base plate 6, then the sand particles 7 which reflected at the base plate are injected to the side wall of the element 1. During this, the air supply amount of the sand particles is controlled as relatively smaller so that it helps the secondary grinding which is made by collided particles.

Another embodiment of a method for processing a substrate according to the invention is a method wherein; one layer is formed by different material on the surface of at least masking side of the substrate, and different material layer formed by different material which has a slower processing speed for blasting than the processing speed of the material used for the substrate. The different material layer is made of a metal layer selected from a group consisting of Cu, Ni, Cr, Ti, Pt, Pd, W, Mo, Zr, Al, Ag and Au or an alloy layer from thereof.

In this embodiment, another material layer is formed on the processed substrate which covered by a masking material. Then, blasting an abrasive to make at least one cross sectional area which is parallel to the base being smaller than either the area of the bottom or top surface of the element. Another material has a slower processing speed than the material used for the substrate when ground by a blasting. More specifically, it is harder to cut than the material used for the substrate when it is processed by a blasting, and another material has a harder than the material used for the substrate, or a sticky material, and its cutting resistance is relatively higher material.

As above, covering a surface of the processed substrate where having another material layer formed thereon by a masking material and blasting an abrasive thereto, it can realize a slow processing speed on the surface of the processed substrate adjacent to another material layer, and make at least one cross sectional area which is parallel to the base being smaller than either the area of the bottom or top surface of the element.

The method of blasting an abrasive may be either injecting vertically to the masking material, injecting at inclined sand particles angel to the side wall of the element, or injecting sand particles at some parts and re-injecting the collided particles to the side wall of the element. A P-type thermoelectric semiconductor wafer is bonded to the electrode fabricated on the surface of the substrate in electrically and mechanically. A P-type thermoelectric semiconductor is made of bismuth and tellurium as a major composition and antimony or selenium or the like are added to optimize its characteristics as additives. The electric circuit metal layer is formed on the surface of the substrate by a metallization, its pattern is arranges as a P-type and N-type element are alternatively connected in series at the final assembly. The substrate is typically made of a non-conductive ceramics such as aluminum, aluminum nitride, silicon carbide or the like. And a silicon or a metal substrate which coated on the surface by a insulating layer are also usable.

The thickness of the wafer is 0.1 mm and a targeting size of the element is size 0.16 mm×0.16 mm. In this example, the side bonded to the substrate of a P-type semiconductor wafer is named as a bottom part and the opposite side is named as a top part. It is carried out by pasting a sand blasting resistive dry film on the wafer, masking the area corresponding to the pattern needed to remain as final elements, and then applying a light exposure and developing.

By this operation, the upper surface of the wafer has a configuration in which the portions to be made as final elements are covered at some intervals.

Then a micro blasting is applied to the wafer and the unnecessary parts are removed. The sand blasting is a micro sand blasting which is suitable to fine processing, and size of the sand particle is within the range from a few micron meter to dozens micron meter. Typically the direction of a sand blasting is vertical, however, in this embodiment, it is declined 45 degree at the most while the vertical is the standard. In this way, the substrate is made where respective elements are arranged thereon.

FIG. 5-4 is a cross sectional view showing an element when a sand blasting is finished in accordance with the invention. The middle part of the element 1 is made like an hour-glass as illustrated in FIG. 5-4 and the cross sectional area of narrow part 5 is smaller than the area of the upper part 2. Although the bottom part 3 is larger than the upper part 2, by means of narrowing the middle part, the difference between the bottom part 3 and the upper part 2 is made within 0.01 mm on one side, and within 0.02 mm on both sides.

Same process was applied for a N-type semiconductor element and same results was obtained. FIG. 5-5 is a schematic cross sectional view showing a thermoelectric element wherein a P-type and a N-type element are connected alternatively in series. As described above, by assembling the substrate 10 having a P-type thermoelectric semiconductor element 1 processed as described above with the substrate 20 having a N-type thermoelectric semiconductor element 11 together and bonding the elements to the electrodes of the corresponding substrate, the thermoelectric element can be obtained wherein P-type and N-type elements are connected alternatively in series.

In this example of the present invention, the elements were arranged with high density, because the difference of the width between the top surface and bottom surface of the elements is so small as 0.02 mm, when the spacing of the electrical circuit be made to 0.03 mm, the spacing between the neighboring elements can be made as 0.05 mm.

As a comparison sample, a cross sectional view showing an element processed by a conventional sand blasting which has not forming a vent part is shown in FIG. 5-9. And a thermoelectric element that including a PN bonding is shown in FIG. 5-10.

As shown in FIG. 5-9, a trailing of the skirt is so large that the difference of the width between the bottom surface 113 and top surface 112 of the elements was made as 0.03 mm of one side or 0.06 mm of both side. Because of that, if the spacing between the electric circuit is made as 0.03 mm, neighboring elements must be separated at 0.09 mm and elements can not arranged with so high density.

One of the embodiment of the invention is, as described above, a method comprising the steps of:
covering the surface of the P-type or N-type semiconductor element by a masking material in a pre-designed pattern corresponding to the plural elements with a object shape;
blasting an abrasive on the P-type or N-type semiconductor wafer covered by a masking material to make at least one cross sectional area which is parallel to the upper surface or bottom surface of the element being smaller than either the area of the bottom or upper surface of the element;
assembling the P-type and the N-type thermoelectric semiconductor element,
bonding the substrates having a electrodes wherein sandwich shape of the P-type and the N-type thermoelectric semiconductor between them;
a plural pair of P-type and the N-type thermoelectric semiconductor is made connected in series through the electric circuit metal layer and bonding layer; and

a plurality of [symbol] -shaped elements wherein the P-type and the N-type semiconductor are electrically connected in series via the electric circuit metal layer and the bonding layer.

In a method for manufacturing a thermoelectric element according to the invention, when assembling the P-type and the N-type thermoelectric semiconductor element, the processed upper surface of the P-type and the bottom surface of the N-type, and the processed bottom surface of the P-type and the upper surface of the N-type may be placed on the same substrate with electrodes respectively.

The thermoelectric element of the invention is a thermoelectric module manufactured by a process as above comprising:
two insulating substrates aligned opposite;
an electric circuit metal layer fabricated on the each surface of the insulating substrate aligned opposite;
a bonding layer fabricated adjacent to the electric circuit metal layer;
a plural pairs of the P-type thermoelectric semiconductor element and the N-type thermoelectric semiconductor element fabricated adjacent to the bonding layer wherein at least one cross sectional area which is parallel to the base being smaller than either the area of the bottom or top surface of the element.
and a plural of [symbol] -shaped elements comprising a plural pairs of the P-type thermoelectric semiconductor element and the N-type thermoelectric semiconductor element which are electrically connected in series through the electric circuit metal layer.

In accordance with the present invention, it can realize a high area density arrangement of the thermoelectric elements because the spacing between the P-type element and the N-type element can be made significantly narrower.

Furthermore, the method for manufacturing the thermoelectric module of this embodiment according to the invention comprises the steps of;
making a wafer which comprising a N-type or a P-type semiconductor element which having a metal layer on the upper surface and a bonding metal layer consisting of a metal electrode/bonding material on the bottom surface;
fixing the wafer of the N-type or P-type semiconductor element in the configuration that the bottom surface positioned with a temporary fixing jig;
slicing the wafer into a discrete element in the pre-designed dimensions;
preparing the insulating substrate having an electric circuit metal layer on the one surface where the protruding portion formed thereon;
forming a bonding material as a bonding layer on the protruding portion corresponding to the position for the elements in the electric circuit pattern,
bonding the bonding material on the insulating substrate with the discrete elements sliced on the temporary fixing jig,
preparing the P-type or the N-type semiconductor elements mounted substrate which having a P-type or N-type semiconductor elements mounted on the position for the elements in the electric circuit pattern of the substrate, and
manufacturing the thermoelectric module comprising a plurality of [symbol] -shape elements wherein;
combining the N-type semiconductor elements mounted substrate with the P-type semiconductor elements mounted substrate in the sandwich configuration thereof, and having the N-type semiconductor elements and the P-type semiconductor elements connected electrically in series.

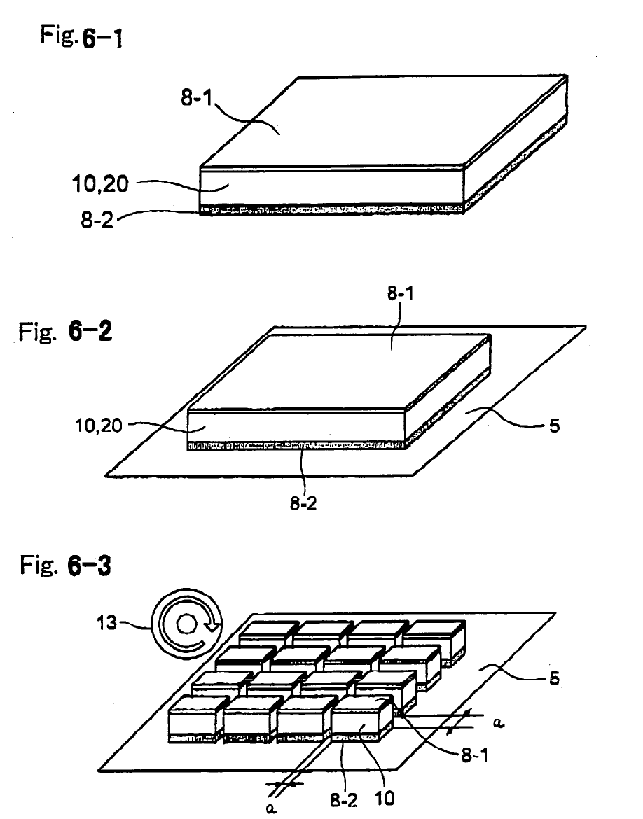

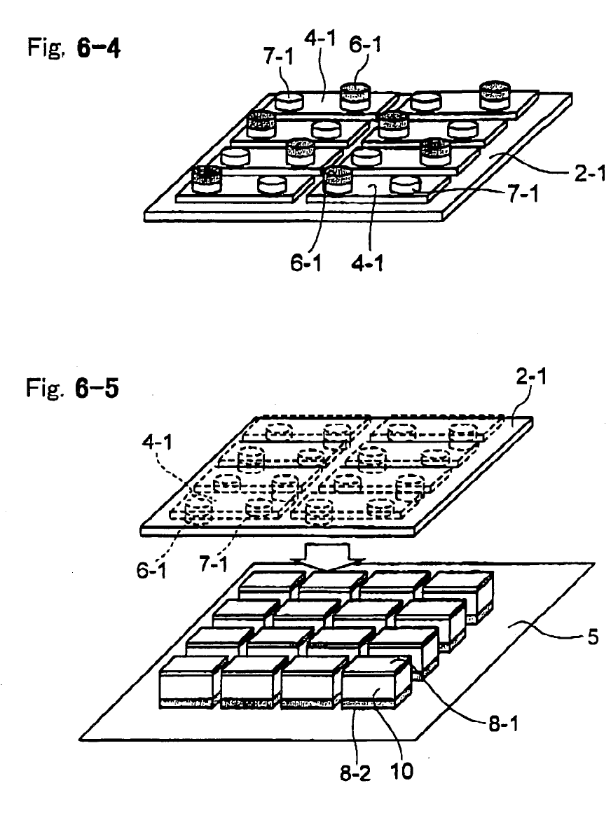

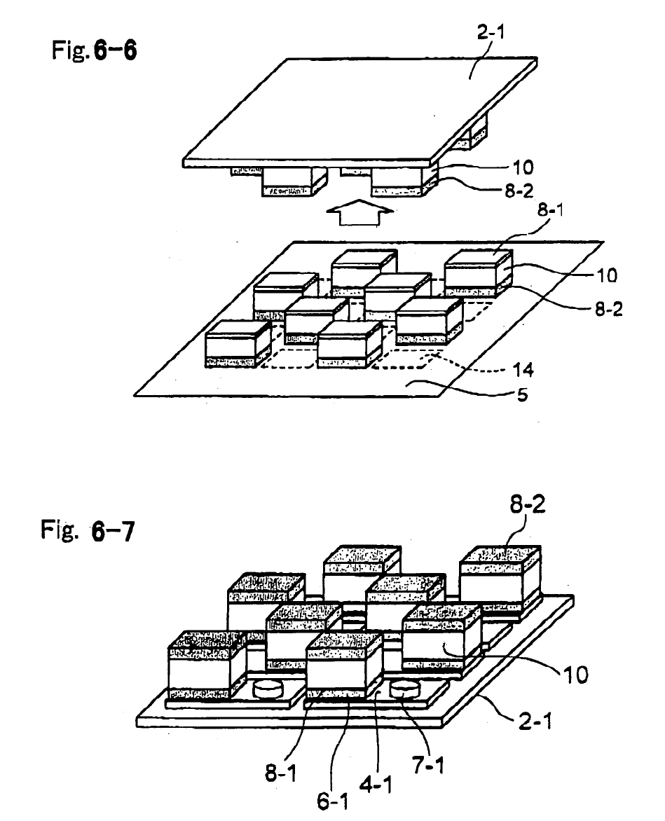

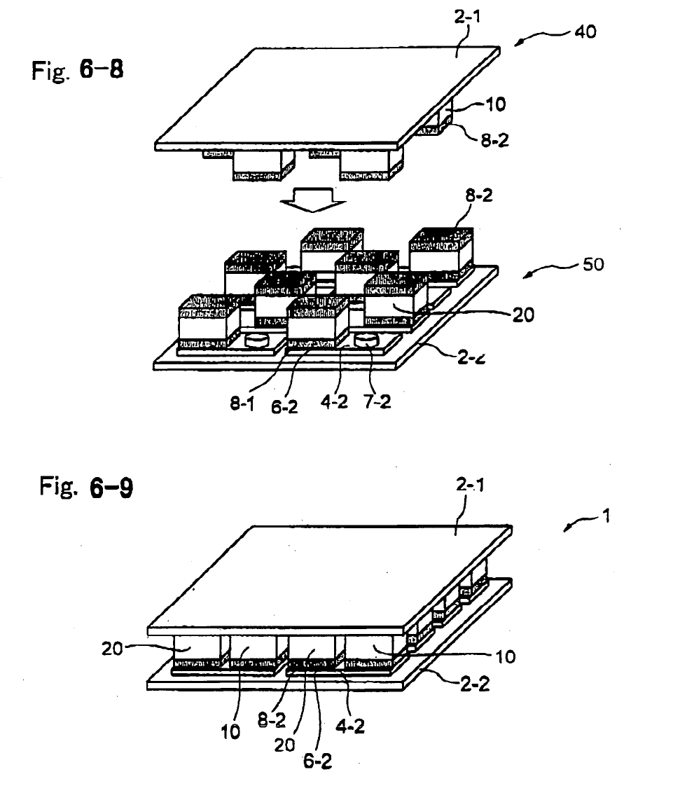

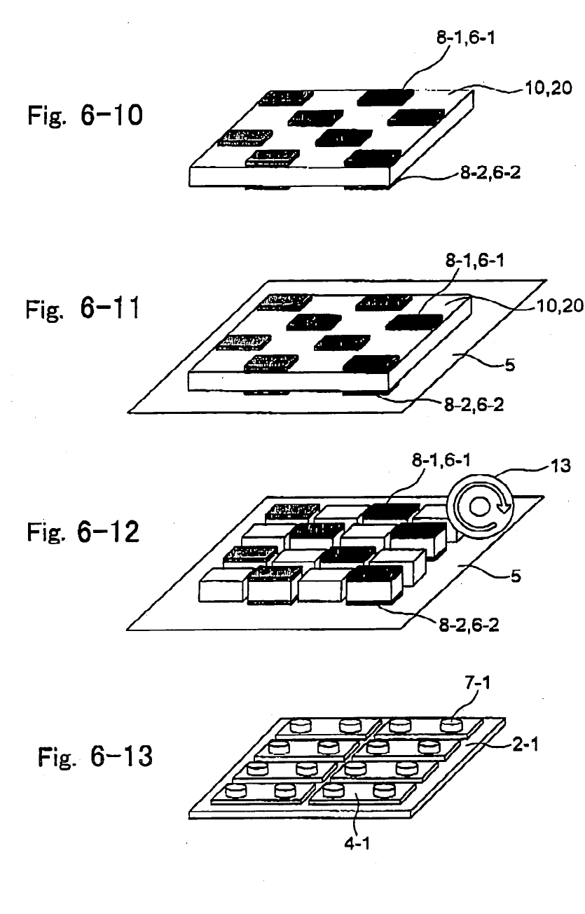

FIG. 6-1 is a drawing showing the wafer comprising the P-type semiconductor element or the N-type semiconductor element which having the bonding metal layer made of a Ni/Au on the upper surface and a Ni/Solder under the lower surface. As illustrated in the FIG. 6-1, on the upper surface of the wafer 10,20 comprising a P-type semiconductor element or a N-type semiconductor element, a bonding metal layer 8-1 made of Ni/Solder is formed and under the lower surface, a bonding metal layer 8-2 made of Ni/Solder is formed.

FIG. 6-2 shows a configuration wherein the wafer having the bonding metal layer formed on both sides is being fixed to a temporary fixing part. As illustrated in the FIG. 6-2, the wafer 10, 20 comprising a P-type semiconductor element or a N-type semiconductor element is placed and fixed wherein an bonding metal layer 8-2 formed under the wafer is being positioned on the temporary fixing plate 5.

FIG. 6-3 shows a configuration wherein the wafer is cut into a discrete element. As illustrated in the FIG. 6-3, for example, the wafer 10 of a P-type semiconductor element is sliced into a discrete element in the pre-designed dimensions horizontally and vertically by a dicing saw. During cutting process, the wafer is fixed to the temporary fixing plate 5 by a tentative heat resistance adhesive, so that the element 10 remains as it without causing a fine movement.

Similarly, a plurality of elements having the bonding metal layer 8-1 made of a Ni/Au on the upper surface and the bonding metal layer 8-2 made of a Ni/Solder under the lower surface are fixed to the temporary fixing plate in order to arrange at fine spacing between them.

FIG. 6-4 shows an insulating substrate having the electric circuit metal layer on one side wherein the protruding portion is formed thereon further. As illustrated in the FIG. 6-4, the electric circuit metal layer is formed on one side of the insulating substrate, wherein the protruding portion 7-1 is formed thereon further. A solder plating 6-1 as a bonding layer is formed on the protruding portions corresponding to the position where the elements are arranged on the circuit pattern of the substrate. Solder plating is carried out on the protruding portions corresponding to the only position where the elements are arranged on the circuit pattern of the substrate.

FIG. 6-5 shows a configuration wherein the sliced elements are joined to the insulating substrate having the electric circuit metal layer, the protruding portion and the solder plating formed thereon. It is shown in the bottom part of the FIG. 6-5 that the plural elements 10 are aligned in order with fine spacing and fixed to the temporary fixing plate 5 wherein having the bonding metal layer 8-1 made of a Ni/Au on the upper surface and the bonding metal layer 8-2 made of a Ni/Solder under the lower surface. On that, after reversing the insulating substrate shown in the FIG. 6-4 up and down, it is joined after moving from the top.

In other words, a plurality of solder plating parts 6-1 as a bonding layer that is formed on the protruding portions where corresponding to the position where the elements are arranged on the circuit pattern of the substrate, are joined to the plural elements arranged on the temporary fixing plate. Consequently, a protruding portion which is not corresponding to the position for the element arranged on the circuit pattern of the substrate, is not bonded to the element arranged on the temporary fixing plate.

FIG. 6-6 is an explanatory drawing showing elements which is bonded to the substrate and elements which is not bonded but remains on the temporary fixing plate. As illustrated in the FIG. 6-6, a plurality of the solder plating part 6-1 as a bonding layer that is formed on the protruding portions where corresponding to the position where the elements are arranged on the circuit pattern of the substrate are joined to the plurality of elements 10 arranged on the temporary fixing plate and moves upwards along with the insulating substrate2-1, and the protruding portions which is not corresponding to the position where the elements are arranged on the circuit pattern of the substrate is not joined to the plurality of elements and elements 10 remains on the temporary fixing plate. The original position before the element moves along with an insulating substrate2-1 is shown by 14.

Some of the elements 10 aligned in order at fine spacing on the temporary fixing plate 5, that is, the elements which corresponding to the position for the element arranged on the circuit pattern of the substrate are transferred to the substrate 2-1. When transferring, the power of adhesive material is needed to weaken. For example, when radiating the special light such as a UV (Ultra Violet ray), it weakens (or lost of adhesive strength).

FIG. 6-7 shows a configuration wherein the elements transferred to the substrate by a method shown in FIG. 6-6 is turned upside-down as the substrate become lower side. As shown in the FIG. 6-7, the electric circuit metal layer 4-1 is formed on the insulating substrate 2-1, and the bonding metal layer 8-1 made of a solder plating 6-1 and Ni/Au formed on the a protruding portion, and the elements 10 are placed at the position of the arrangement on the circuit pattern of the substrate. In the FIG. 6-7, on the upper surface of the element 10, the bonding metal layer 8-2 made of a Ni/Solder formed on the protruding portion and placed adjacent to the temporary fixing plate before transferring.

By same step as described referring to FIG. 6-1 through FIG. 6-7, preparing the wafer from a N-type semiconductor element, slicing into a discrete element 20 in the pre-designed dimensions, transferring the element 20 which placed at the position of the arrangement on the circuit pattern of the substrate onto the substrate which having the solder plating, the protruding portions and the electric circuit metal layer

FIG. 6-8 is an explanatory drawing showing the configuration wherein the P-type semiconductor mounting substrate having the P-type semiconductor elements on the circuit pattern of the substrate and the N-type semiconductor mounting substrate having the N-type semiconductor elements are assembled together. As shown in FIG. 6-8, the electric circuit metal layer 4-2 is formed on the insulating substrate 2-2, and during the status of that the bonding metal layer 8-2 made of Ni/Au and the Ni/Solder 6-2 formed on the protruding portion are bonded together, the N-type semiconductor mounting substrate 50 having a element 20 placed at the position of the arrangement on the circuit pattern of the substrate, and the P-type semiconductor mounting substrate 40 having a element 10 placed at the position of the arrangement on the circuit pattern of the substrate are assembled together. That is, the protruding portion 7-2 on the N-type semiconductor mounting substrate 50 and an bonding metal layer made of Ni/Solder on the P-type semiconductor mounting substrate 40 are bonded together.

As a result, as illustrated in FIG. 6-9, the thermoelectric module comprising a plurality of [symbol] shape elements is made wherein the N-type semiconductor elements and the P-type semiconductor elements which are placed between two insulating substrates and connected electrically in series.

FIG. 2-1 is an explanatory sectional view of one embodiment of the thermoelectric module in accordance with the invention. As illustrated in FIG. FIG. 2-1, the thermoelectric module of the invention comprises:
two insulating substrates 2-1, 2-3 aligned opposite,
the electric circuit metal layer 4-1, 4-2 fabricated on the each surface of the insulating substrate aligned opposite,
a plural pairs of P-type semiconductor element 10 and N-type semiconductor element 20 which having an bonding metal layer 8-1, 8-2 on both sides where the bonding layer 6-1, 6-2 further thereon, and
a plural pairs of P-type semiconductor element 10 and N-type semiconductor element 20 which are electrically connected in series through the electric circuit metal layer 4-1,4-2 and forming a [symbol] -shaped elements.

The width of cutting “a” is less than 50 micron meter, 15 micron meter-30 micron meter is a preferable range. Because the wafer having a bonding metal layer is fixed on the temporary fixing plate and cut by a dicing equipment, there is no limitation with the height of the element, for example, it is possible to lower as 100 micron meter-200 micron meter.

As described, solder plating formed on the protruding portion is bonded together with a bonding metal layer made of Ni/Au, the elements on the circuit pattern of the substrate are separated from the temporary fixing plate, transferred onto the insulating substrate, rest of the elements remain on the temporary fixing plate.

The remaining elements, both of the P-type semiconductor element 10 and the N-type semiconductor element 20, can be used as the element of the circuit pattern of the substrate by rotating the substrate on the same plane. Therefore, the element can be used efficiently without vain.

Furthermore as described above, in the method for manufacturing the thermoelectric module according to the invention, when assembling the P-type semiconductor mounting substrate with the N-type semiconductor element, a bonding metal layer made of a Ni/Solder on the bottom side of the element is bonded to the top part of the protruding portion which a solder plating as a bonding layer is not formed thereon.

A thermoelectric module of the present invention is a thermoelectric module manufactured by the process described above. A thermoelectric module of the present invention comprises the steps of:
preparing the insulating substrate having an electric circuit metal layer on one side and surface where the protruding portion formed thereon further;
forming a solder plating as a bonding layer on the protruding portion corresponding to the position for the elements in the electric circuit pattern;
preparing a wafer comprising a P-type or N-type semiconductor elements which having a bonding metal layer made of Ni/Au on the upper surface and a Ni/Solder under the lower surface;
fixing the wafer wherein the bonding metal layer being positioned over the temporary fixing plate;
slicing the wafer into a discrete element 20 in the pre-designed dimensions;
bonding a solder plating formed on the insulating substrate with the elements sliced on the temporary fixing plate;
assembling the N-type or the P-type semiconductor elements mounting substrate having the N-type semiconductor element placed at the position for the elements on the circuit pattern of the substrate or the P-type respectively;
forming the thermoelectric module comprises;
an electric circuit metal layer fabricated on the each surface of the insulating substrate aligned opposite;
bonding layers including the bonding layer fabricated adjacent to the electric circuit metal layer;
the bonding metal layer made of Ni/Au on the upper surface and a Ni/Solder under the lower surface fabricated adjacent to the bonding layer, and
a plurality of [symbol] shape elements is made wherein the P-type semiconductor elements and the N-type semiconductor elements which are placed between two insulating substrates and connected electrically in series.

In addition to the embodiment described above, as illustrated in FIG. 6-10 through FIG. 6-13, another step is forming the bonding metal layer and the bonding layer on the upper and lower surface of the element in advance, then bonding with the electric circuit metal layer including the protruding portion.

FIG. 6-10 shows wafers made of a P-type semiconductor or a N-type semiconductor where a bonding metal layer and a bonding layer are fabricated on the upper side and lower side respectively.

As illustrated in FIG. 6-11, on the wafer 10, 20, a bonding metal layer 8-1, 8-2 are fabricated on the upper side of the wafer 10, 20 and a bonding layer 6-1,6-2 is on the lower side respectively. The position of the bonding metal layer and the bonding layer is determined by the position of the protruding portion corresponding to the position for the elements in the electric circuit pattern.

FIG. 6-11 shows a configuration wherein the wafer having a bonding metal layer and a bonding layer fabricated on both sides (a bonding metal layer on the wafer first, and a bonding layer next) is being fixed to a temporary fixing plate. As illustrated in FIG. 6-11, the wafer 10, 20 which comprises a P-type semiconductor or N-type semiconductor element is placed and fixed wherein a bonding metal layer 8-2 and the bonding layer 5-2 are formed under surface of the wafer is being positioned on the temporary fixing plate 5.

FIG. 6-12 shows a configuration of the wafer after slicing into discrete element.

As illustrated in FIG. 6-12, the wafer 10, for example, of the P-type semiconductor is cut along by the bonding metal layer horizontally and vertically by a dicing equipment. During cutting process, the wafer 10 is fixed to the temporary fixing plate 5 by a tentative heat resistance adhesive, so that the element 10 remains as it without causing a fine movement. As this process, a plurality of elements having the bonding metal layer 8-1 and the bonding layer 6-1 fabricated on the upper surface and a bonding metal layer 8-2 and the bonding layer 6-2 fabricated on the lower surface, and a plurality of elements having neither the bonding metal layer nor the bonding layer fabricated are aligned in order at fine spacing and fixed to the temporary fixing plate.

Similarly, for the N-type semiconductor wafer 20, a plurality of elements 20 having the bonding metal layer 8-1 and the bonding layer 6-1 fabricated on the upper surface and the bonding metal layer 8-2 and the bonding layer 6-2 fabricated on the lower surface and a plurality of elements having neither the bonding metal layer nor the bonding layer fabricated are aligned in order at fine spacing and fixed to the temporary fixing plate 5.

FIG. 6-13 shows a substrate wherein the electric circuit metal layer formed and the protruding portion is formed further thereon. As illustrated in FIG. 6-13, the electric circuit metal layer 4-1 is formed on the insulation substrate and a protruding portion 7-1 is formed further thereon.

By the same step as described referring to the FIG. 6-5 through FIG. 6-9, the insulation substrate having the electric circuit metal layer and the protruding portion are formed is bonded to the elements which is sliced.

Then, a protruding portion corresponding to the position for the elements in the electric circuit pattern is joined to a plurality of the elements 10 which is placed on the temporary fixing plate 5 and moving upwards along with the insulating substrate 2-1 and the protruding portions which is not corresponding to the position for the elements of the circuit pattern on the substrate is not joined to the plurality of elements on the temporary fixing plate, and hence the elements 10 remain on the temporary fixing plate.

In this way, some of the elements 10 aligned in order at fine spacing and fixed to the temporary fixing plate 5, that is, the elements placed at position for the elements of the circuit pattern of the substrate are separated from the temporary fixing plate having an electric circuit metal layer and a bonding layer is, transferred onto the insulating substrate 2-1.

Like this, the P-type semiconductor elements mounting substrate having the P-type semiconductor element placed at the position for the elements are formed, the N-type semiconductor elements mounting substrate having the N-type semiconductor element placed at the position for the elements are formed, and thus formed substrates are assembled, and the thermoelectric module comprises a plurality of [symbol] shape elements is made wherein the P-type semiconductor elements and the N-type semiconductor elements which are placed between two insulating substrates 2-1 and 2-2 and connected electrically in series.

The thermoelectric module in accordance with the present invention has following advantages compared to the conventional thermoelectric module.

Especially, because a micro blasting is used on the intermetalic compound such as Bi—Te group of semiconductor, its processing speed is much faster and also any arbitrary shape of thermoelectric module can be made.

In addition, it can be made without filling a synthetic resin, for example an epoxy resin, in the space between electrodes of thermoelectric element.

Further important advantage is the significantly high density of arrangement of the small thermoelectric elements, when comparing it in terms of the heat absorption capacity, the area of the substrate can be made to half or less than the conventional dimensions. The compact size means not only effective for the space saving but also power consumption saving. One example shows that it saves 50% of the required power when absorbing a heat from a semiconductor laser module.

According to the present invention, during the perforation process carried out by a sand blasting, the side wall can be made about vertical plane, as a result, it makes possible to process a fine element at high accuracy and hence the thermoelectric module can be manufactured at high area density of the elements and at high performance.

Furthermore, the methods according to the present invention provides a module comprising a micro element such as a micro electric element, micro semiconductor element, and a method of bonding with narrow pitch at low cost. That is, it provides a thermoelectric module having a micro element which allows high area density mounting at narrow pitch by preventing an excess bonding by means of constructing a container within the electric circuit metal layer of the substrate to absorb an excess bonding material which is forced out by pressure when bonding electrodes of a micro element and an electric circuit metal layer of the corresponding substrate via a bonding layer. Also, it is possible to reduce the manufacturing cost by constructing the container, because a tight height control may not be needed but only requires to press at pre-designed pressure on the micro element.

And, when an electrical resistance and heat resistance of the module is needed to limit to lower value, a high performance module can be provided because a protruding portion of the electric circuit metal layer of the substrate is made of a low electrical resistance and low heat resistance material such as Cu, and the protruding portion can be mounted closely with a micro electric element and a micro semiconductor element.

Furthermore, where a module having at least one cross sectional area which is parallel to the base is smaller than either the area of the upper or lower part of the element, by closing the difference between the area of the upper and the lower part of the element, the required area density of the elements can be made, as a result, high performance module can be manufactured.

According to the present invention, it provides a method for manufacturing a small and high performance thermoelectric module wherein a P-type and N-type thermoelectric semiconductor elements can be arranged freely any place, the spacing between the thermoelectric semiconductor elements can be made narrower, and capable of thermo controlling for the small area. Furthermore, it provides a method for manufacturing a thermoelectric module with high efficiency in terms of material usage as the cutting width of the wafer is small, and the part to be cut off is significantly small.

1. A thermoelectric module comprises:
(a) an upper insulating substrate and a lower insulating substrate;
(b) an upper electric circuit metal layer and a lower electric circuit metal layer bonded respectively to the surfaces of said insulating substrates which are positioned face to face;
(c) an upper blast stopper layer and a lower blast stopper layer fabricated respectively on said electric circuit metal layers;
(d) an upper bonding layer and a lower bonding layer fabricated respectively on said blast stopper layers; and
(e) a plurality of [symbol] -shaped elements consisting of a pair of the P-type semiconductor element and N-type semiconductor element which are fabricated between said upper and lower bonding layers and are electrically connected in series through said upper and lower blast stopper layers.

2. A thermoelectric module comprises:
(a) an upper insulating substrate and a lower insulating substrate;
(b) an upper electric circuit metal layer and a lower electric circuit metal layer bonded respectively to the surfaces of said insulating substrates which are positioned face to face;
(c) an upper bonding layer and a lower bonding layer fabricated respectively on said electric circuit metal layers;
(d) an upper blast stopper layer and a lower blast stopper layer fabricated respectively on said bonding layers; and
(e) a plurality of [symbol] -shaped elements consisting of a pair of the P-type semiconductor element and N-type semiconductor element which are fabricated between said upper and lower blast stopper layers and are electrically connected in series through said upper and lower blast stopper layers.

3. A method for manufacturing a thermoelectric module comprising an upper and a lower insulating substrates, electric circuit metal layers bonded respectively to the surfaces of said substrate which are positioned face to face, blast stopper layers fabricated respectively on said electric circuit metal layers, bonding layers fabricated on said blast stopper layers; and a plurality of [symbol] -shaped elements consisting of a pair of the P-type semiconductor element and N-type semiconductor element which are fabricated between said bonding layers and are electrically connected in series through said upper and lower blast stopper layers,
said method comprises the steps of:
preparing the substrate having the electric circuit metal layer and the blast stopper layer in a pre-designed pattern;
preparing a plate type P-type or N-type semiconductor having the bonding layer fabricated thereon;
bonding the surface of the bonding layer to the blast stopper layer fabricated on said substrate;
coating a photoresist;
forming a pre-designed pattern by an exposure;
further, by a micro blasting an abrasive, eliminating said bonding layer and said semiconductor layer of the area where the photoresist has been removed;
constructing a first part having said semiconductor layer protruded from one side of said substrate;
removing a residue of the photoresist;
and by repeating the same process as described above, constructing a second part using a different polarity semiconductor of a P-type or N-type from said first part which has a shape wherein the P-type and N-type are arranged alternatively when assembled facing to the first part;
then, reversing said second part by 180 degree, mating to the first part and bonding both parts together.

4. A method for manufacturing a thermoelectric module comprising an upper and a lower insulating substrates, electric circuit metal layers bonded respectively to the surfaces of said substrates which are positioned face to face, bonding layers fabricated respectively on said electric circuit metal layers, blast stopper layers fabricated respectively on said bonding layers; and a plurality of [symbol] -shaped elements consist of a pair of the P-type semiconductor element and N-type semiconductor element which are fabricated between said blast stopper layers and are electrically connected in series through said upper and lower blast stopper layers,
said method comprises the steps of:
preparing the insulating substrate having the electric circuit metal layer and the bonding layer in a pre-designed pattern;
preparing the plate of P-type or N-type semiconductor having the blast stopper layer fabricated thereon;
bonding the surface of said blast stopper layer to the bonding layer fabricated on said substrate;
coating a photoresist;
forming a pre-designed pattern by an exposure;
further, by a micro blasting, eliminating said semiconductor layer of the area where the photoresist has been removed;
constructing a first part having said semiconductor layer protruded from one side of said substrate;
removing the residue of the photoresist;
and by repeating the same process as described above, constructing a second part using a different polarity semiconductor of a N-type or P-type from said first part which has a shape wherein the P-type and N-type are arranged alternatively when assembled facing to the first part;
then, reversing said second part by 180 degree, mating to the first part,
and bonding both parts together.

5. A thermoelectric module comprises a plurality of [symbol] -shaped elements consisting of a pair of P-type semiconductor element and N-type semiconductor element which are electrically connected in series through said electric circuit metal layers and said bonding layers, which including:
two insulating substrates which are positioned face to face;
electric circuit metal layers fabricated respectively on the surfaces of said insulating substrates;
bonding layers fabricated respectively on the electric circuit metal layers; and
a plurality of pairs of P-type semiconductor element and N-type semiconductor element formed by a micro blasting applied from the both ends, which are fabricated on said bonding layers and have respective bonding metal layers on both sides thereof.

6. A thermoelectric module comprises a plurality of n shape elements consisting of a pair of P-type semiconductor element and N-type semiconductor element which are electrically connected in series through said electric circuit metal layers, which including:
two insulating substrates which are positioned face to face;
electric circuit metal layers fabricated respectively on the surfaces of said insulating substrates;
a plurality of pairs of P-type semiconductor and N-type semiconductor formed by a micro blasting applied from the both ends, which are fabricated on said electric circuit metal layers and have respective bonding metal layers on both sides and the bonding layers further fabricated respectively thereon.

7. A method for manufacturing a thermoelectric module comprising a plurality of [symbol] -shaped elements consist of a pair of P-type and N-type semiconductor element which are sandwiched between two insulating substrates and electrically connected in series, and said method comprises the steps of:
preparing the insulating substrate having the electric circuit metal layer formed on one side, and a plate type N-type semiconductor element and P-type semiconductor element having bonding metal layers fabricated respectively on the upper and lower side thereof;
forming a bonding layer on said electric circuit metal layer or said bonding metal layer;
applying a micro blasting on one side of said plate type N-type or P-type semiconductor;
bonding a blasted surface to said insulating substrate;
further applying a micro blasting on another side; and
combining the P-type semiconductor and N-type semiconductor thus prepared which are bonded to the insulating substrate.

8. A method for processing a wafer comprises the steps of:
covering a surface of a wafer to be processed with a mask material in a pre-designed pattern;
placing a supporting part of which a portion corresponding to the mask material is made of a convex part and a remaining portion being a concaved part on a back side of said wafer to be processed; and
blasting an abrasive to said wafer to be processed which is covered by said mask material to perforate an area of said concaved part.

9. The method for processing a wafer in claim 8, wherein a side wall processed by said blasting is formed to be substantially perpendicular.

10. The method for processing a wafer in claim 8 further comprises the step of fixing said wafer to be processed to said supporting part by a fixing means.

11. A method for manufacturing a thermoelectric module comprises the steps of:
placing a thermoelectric semiconductor wafer being contact to a surface of convex parts on a supporting part wherein the supporting part has a plurality of convex parts arranged on a flat plate corresponding to an object shape of the thermoelectric semiconductor wafer to be processed;
placing a film like material on said thermoelectric semiconductor wafer; exposing and developing the film like material and forming a predetermined shape of masking material corresponding to said shape to be processed of said thermoelectric semiconductor wafer;
blasting an abrasive on the thermoelectric semiconductor wafer which is covered by said masking material to perforate in concave part which surrounds the convex part;
forming an arranged plurality of pillars comprising said convex part, thermoelectric semiconductor element and masking material; and
removing said masking material.

12. The method for manufacturing a thermoelectric module in claim 11 further comprises the step of transferring said thermoelectric semiconductor elements to the transferring part after the masking material removed, wherein the transferring of said thermoelectric semiconductor element to said transferring part moves said P-type thermoelectric semiconductor elements and N-type thermoelectric semiconductor elements to the same transferring part or different transferring part respectively, consequently it forms the P—N elements arrangement.

13. A supporting substrate wherein a wafer to be processed by blasting an abrasive is positioned thereon,
and including a plurality of convex parts and a plurality of concave parts which forms circumference of said convex part which arranged corresponding to a pre-designed pattern of said wafer to be processed.

14. A module including a plurality of micro elements mounted at high density on a substrate wherein electrodes of said micro element and corresponding electric circuit metal layer of said substrate are bonded via bonding layer, and said electric circuit metal layer of said substrate has a container portion to absorb an excess bonding material which is used to form said bonding layer when it is forced out by pressure.

15. The module including a micro element in claim 14, wherein said electric circuit metal layer consists of a flat plate and a protruding portion, said protruding portion is formed on the side facing to said micro element, and said container consists of said protruding portion, said flat plate and said electrode of said micro element.

16. A method for narrow pitch bonding of a plurality micro elements at high density on a substrate comprises the steps of:
providing a protruding portion on the electric circuit metal layer of said substrate corresponding to the electrode of said micro element,
placing a suitable amount of bonding material to form the bonding layer between said electrode of said micro element and said protruding portion,
pressing said micro element towards said electric circuit metal layer of said substrate through said bonding material and containing an excess part of said bonding material in the space made by said protrude and said electrode of said micro element, and
forming said bonding layer.

17. A method for processing a wafer comprises the steps of:
covering a surface of the wafer to be processed with a masking material of a pre-designed pattern corresponding to an object shape of a plurality of elements; and
blasting an abrasive on said wafer to be processed which has said masking material covered so that at least one plane of the cross sectional areas which parallel to said substrate of said element is made smaller than a smaller area of either top or bottom surface of said element.

18. The method for processing a wafer in the claim 17 wherein
a different material layer is formed on at least one surface of said wafer which is covered with the masking material, and said different material layer is made of a material which is processed slower by the blasting abrasion than said wafer.

19. A method for manufacturing a thermoelectric module comprising a plurality of [symbol] -shaped elements consist of a pair of P-type and N-type semiconductor element which are electrically connected in series via an electric circuit metal layer and a bonding layer, said method comprises the steps of:
covering a surface of a P-type or N-type semiconductor wafer with a masking material of a pre-designed pattern corresponding to an object shape of a plurality of elements;
blasting an abrasive on said P-type or N-type semiconductor wafer which has said masking material covered so that at least one plane of cross sectional areas which are parallel to a top or bottom surface of said element is made smaller than a smaller area of either top or bottom surface of said element;
assembling the P-type and N-type thermoelectric semiconductor elements;
bonding the wafers with the electric circuit metal layer to both surfaces of said assembled P-type and N-type semiconductor elements as sandwiched therebetween.

20. A thermoelectric module comprises a plurality of [symbol] -shaped elements consist of a plurality pairs of P-type thermoelectric semiconductor element and N-type thermoelectric semiconductor element which are electrically connected in series through an electric circuit metal layer and a bonding layer, which including:
two insulating substrates which are positioned face to face;
an electric circuit metal layer fabricated respectively on a surface of said insulating substrate;
a bonding layer fabricated on said electric circuit metal layer;
a plurality of pairs of P-type and N-type semiconductor element fabricated on said bonding wherein at least one plane of cross sectional areas which are parallel to a top or bottom surface is made smaller than a smaller area of either top or bottom surface.

21. A method for manufacturing a thermoelectric module comprising a plurality of [symbol] -shaped elements consist of a pair of P-type and N-type semiconductor element which are sandwiched between two insulating substrates and electrically connected in series, said method comprises the steps of:
forming a wafer consisting of a P-type semiconductor element or N-type semiconductor element respectively which has a metal electrode fabricated on a top surface thereof and a metal electrode/bonding material on a bottom surface thereof;
fixing said wafer consists of a P-type semiconductor element or N-type semiconductor element as said bottom side being positioned on a temporary supporting part;
slicing said ware to discrete elements in a pre-designed dimensions;
preparing an insulating substrate having the electric circuit metal layer on one side with a protruding portion fabricated further thereon;
forming a bonding material as a bonding layer on said protruding portion corresponding to a respective area of elements arranged on a substrate circuit pattern;
boding said bonding material of said insulating substrate to said elements which are cut on said temporary supporting part,
preparing a substrate with P-type semiconductor elements or N-type semiconductor elements mounted thereon wherein said P-type semiconductor element or N-type semiconductor element are correspondingly arranged on said substrate circuit pattern;
assembling thus prepared substrates with P-type semiconductor elements and N-type semiconductor elements mounted respectively thereon.

22. A thermoelectric module comprising electric circuit metal layers respectively fabricated on each surface of the substrates aligned opposite, bonding layers including a protruding portion fabricated on the electric circuit metal layer, a metal electrode on the top surface and a metal electrode/bonding material on the bottom surface fabricated adjacent to said bonding layer, a plurality of [symbol] -shaped elements consisting of a P-type semiconductor element and N-type semiconductor element electrically connected in series as sandwiched by two insulating substrates, which is manufactured by the steps of:
fabricating an insulating substrate having an electric circuit metal layer on one side and a protruding portion further on the electric circuit metal layer;
fabricating a bonding material as a bonding layer on said protruding portions corresponding to elements arranged on a substrate circuit pattern;
fabricating a wafer consisting of a P type semiconductor element or N type semiconductor element respectively which has a metal electrode formed on a top surface and a element bonding surface metal layer comprising a metal electrode/bonding material on a bottom surface, a discrete element being made in a dimension as pre-designed from said wafer;
assembling together a P-type semiconductor element mounting substrate and a N-type semiconductor element mounting substrate thus prepared wherein said bonding material of said insulating substrate is bonded to said elements, and the elements consisting of said P-type semiconductor element or N-type semiconductor element are arranged in the area for the elements on the substrate circuit pattern.

23. The method for processing a wafer in claim 9 further comprises the step of fixing said wafer to be processed to said supporting part by a fixing means.
